(19) United States
(12) Patent Application Publication
(10) Pub. No.: US 2025/0357355 A1
(43) Pub. Date: Nov. 20, 2025

(54) CIRCUIT BOARD AND SEMICONDUCTOR PACKAGE COMPRISING SAME

(71) Applicant: LG INNOTEK CO., LTD., Seoul (KR)

(72) Inventors: Kee Han LEE, Seoul (KR); Sang II Kim, Seoul (KR); Se Woong NA, Seoul (KR)

(21) Appl. No.: 18/696,535

(22) PCT Filed: Sep. 28, 2022
(86) PCT No.: PCT/KR2022/014513

§ 371 Date: Oct. 30, 2024

(30) Foreign Application Priority Data
Sep. 28, 2021 (KR) 10-2021-0128395

(51) Int. Cl. H01L 23/538; H05K 1/11; H05K 1/18

(52) U.S. Cl. CPC H01L 23/5386; H05K 1/117; H05K 1/181

(57) ABSTRACT

A circuit board according to an embodiment includes an insulating layer; a circuit pattern layer disposed on the insulating layer; and a protective layer disposed on the insulating layer and the circuit pattern layer and including a plurality of openings, wherein the openings includes a plurality of first openings and a plurality of second openings, wherein the first opening overlaps vertically with an upper surface of a pad of the circuit pattern layer and does not overlap horizontally with a side surface of the pad, and wherein the second opening overlaps vertically with an upper surface of a pad of the circuit pattern layer and horizontally with at least a portion of a side surface of the pad.

### TECHNICAL FIELD

The embodiment relates to a circuit board and a semiconductor package including the same.

### BACKGROUND ART

Generally, a printed circuit board (PCB) is a laminated structure in which insulating layers and conductor layers are alternately laminated, and the conductor layers may be provided with a circuit pattern by patterning.

Such printed circuit board includes a solder resist SR that protects the circuit pattern formed on an outermost side of the laminate structure, prevents oxidation of the conductor layer, and serves as an insulator when electrically connected to a chip mounted on a printed circuit board or another board.

A typical solder resist includes an opening region (SRO: Solder Resist Opening) where connection means such as solder or bumps are combined to form an electrical connection path. The opening region of the solder resist is required as the I/O (Input/Output) performance improves as the high performance and density of printed circuit boards increase, thereby a small bump pitch of the opening region is required. At this time, the bump pitch of the opening region refers to a center distance between adjacent opening regions.

Meanwhile, the opening region SRO of the solder resist includes a Solder Mask Defined (SMD) type and a Non-Solder Mask Defined (NSMD) type.

The SMD type is characterized in that a width of the opening region SRO is smaller than a width of the pad exposed through the opening region SRO, and accordingly, in the SMD type, at least a portion of an upper surface of the pad is covered by the solder resist.

In addition, the NSMD type is characterized in that a width of the opening region SRO is larger than a width of the pad exposed through the opening region SRO, and accordingly, the solder resist in the NSMD type is spaced apart from the pad at a certain interval and has a structure in which both the upper and side surfaces of the pad are exposed.

However, in the case of the above SMD type, when testing the solder ball joint reliability of a bonding strength of the solder ball after a semiconductor package is connected to a main board, there is a problem in that the solder ball is separated from the pad exposed through the opening region SRO. Additionally, in the case of the NSMD type, there is a problem in that the pad on which the solder ball is disposed is separated from the circuit board. Accordingly, conventionally, an appropriate combination of SMD type and NSMD type is applied to one circuit board.

In a conventional circuit board, a stress applied to each region varies, and accordingly, there is a difference in a bonding strength between a pad and a solder ball and between a pad and an insulating layer depending on a position of a pad. However, the conventional circuit board forms an SMD-type opening region or an NSMD-type opening region in the solder resist without any consideration of the stress for each area as described above, as a result, there is a problem that the physical reliability of the circuit board is reduced.

### DISCLOSURE

### Technical Problem

An embodiment provides a circuit board with a new structure and a semiconductor package including the same.

Additionally, the embodiment provides a circuit board including a protective layer designed in consideration of stress applied by region or location, and a semiconductor package including the same.

Additionally, an embodiment provides a circuit board including a protective layer having a plurality of openings of different types formed in one pad and a semiconductor package including the same.

Additionally, the embodiment provides a circuit board including a protective layer having a new type of opening and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

In addition, the protective layer includes a first region of a central region and a second region of an outer region excluding the central region, and a number of first openings formed in the first region of the protective layer is greater than a number of first openings formed in the second region of the protective layer.

In addition, a number of second openings formed in the second region of the protective layer is greater than a number of second openings formed in the first region of the protective layer.

In addition, the number of first openings formed in the first region of the protective layer is greater than the number of second openings formed in the first region of the protective layer, and the number of second openings formed in the second region of the protective layer is greater than the number of first openings formed in the second region of the protective layer.

In addition, the first region of the protective layer is a central region of a chip mounting region, and the second region of the protective layer is an outer region of the chip mounting region excluding the central region of the chip mounting region.

In addition, the first region of the protective layer is a central region of an entire upper region or an entire lower region of the insulating layer, and the second region of the protective layer is an outer region of the entire upper region or the entire lower region excluding the central region of the entire upper region or the entire lower region.

In addition, the circuit pattern layer includes at least one of a first-first pad and a first-second pad vertically overlapping with the first opening, the first-first pad vertically overlaps a plurality of first openings spaced apart from each other in a width or longitudinal direction, and first-second pad vertically overlaps one first opening.

In addition, the second opening includes a second-first opening, the circuit pattern layer includes a first-third pad vertically overlapping the second-first opening, an entire region of an upper surface of the first-third pad vertically overlaps the second-first opening, an entire region of a side surface of the first-third pad overlaps horizontally with the second-first opening, and the insulating layer includes a non-overlapping region that vertically overlaps the second-first opening and does not vertically overlap the circuit pattern layer and the protective layer.

In addition, the second opening includes a second-second opening, the circuit pattern layer includes a first-fourth pad vertically overlapping the second-second opening, an entire region of an upper surface of the first-fourth pad vertically overlaps the second-second opening, and a side surface of the first-fourth pad partially overlaps the second-second opening horizontally, and the protective layer includes a supporting portion that vertically overlaps the second-second opening and is in direct contact with the side surface of the first-fourth pad.

In addition, the protective layer includes a third opening spaced apart from the first opening in a longitudinal or width direction and partially overlapping the first-first pad vertically, and the third opening has a width smaller than a width of the first-first pad, and at least a portion of a side surface of the first-first pad horizontally overlaps the third opening.

In addition, the protective layer includes a fourth opening vertically overlapping the third pad of the circuit pattern layer and having a width greater than the width of the third pad, the third pad includes a first side surface and a second side surface, the first side surface of the third pad overlaps horizontally with the fourth opening and is spaced apart from the protective layer, and the second side surface of the third pad partially overlaps the fourth opening horizontally and including at least a portion in contact with the protective layer.

In addition, the circuit pattern layer includes a fourth pad and a trace disposed on a first side surface of the fourth pad, the protective layer includes a fifth opening that partially overlaps the fourth pad vertically, an upper surface of the fourth pad includes a first overlapping region that vertically overlaps the fifth opening, and a second overlapping region that vertically overlaps the protective layer.

In addition, the second overlapping region is a first outer region of the upper surface of the fourth pad adjacent to the first side surface of the fourth pad.

In addition, the first overlapping region includes a central region of an upper surface of the fourth pad, and a second outer region excluding the first outer region among an outer region of the upper surface of the fourth pad.

In addition, the first side surface and the trace of the fourth pad are covered with the protective layer.

In addition, the fourth pad includes a second side surface adjacent to the second outer region, at least a portion of the second side surface of the fourth pad overlaps horizontally with the fifth opening and does not contact the protective layer.

Meanwhile, the circuit board according to the embodiment comprises a first outermost insulating layer; a first outermost circuit pattern layer disposed on the first outermost insulating layer; a first protective layer disposed on the first outermost insulating layer and the first outermost circuit pattern layer and including a plurality of openings; a second outermost insulating layer disposed under the first outermost insulating layer; a second outermost circuit pattern layer under the second outermost insulating layer; a second protective layer disposed under the second outermost insulating layer and the second outermost circuit pattern layer and including a plurality of openings; wherein each opening of the first protective layer and the second protective layer includes a first opening that vertically overlaps a pad of the first outermost circuit pattern layer or the second outermost circuit pattern layer and does not horizontally overlap a side surface of the pad, and a second opening that overlaps vertically with a pad of the first outermost circuit pattern layer or the second outermost circuit pattern layer and horizontally overlaps at least a portion of a side surface of the pad, the first protective layer includes a first central region of a chip mounting region and a first outer region excluding the first central region of the chip mounting region, a number of second openings formed in the first outer region of the first protective layer is greater than a number of second openings formed in the first central region of the first protective layer, and the second protective layer includes a second central region of an entire lower region of the second outermost insulating layer and a second outer region of the entire lower region excluding the second central region of the entire lower region, and a number of second openings formed in the second outer region of the second protective layer is greater than a number of second openings formed in the second central region of the second protective layer.

### Advantageous Effects

As described above, the embodiment includes an insulating layer, a circuit pattern layer disposed on the insulating layer, and a protective layer partially disposed on the insulating layer and the circuit pattern layer.

At this time, the protective layer may be divided into a first region and a second region. The first region of the protective layer may correspond to a chip mounting region where a chip is mounted, and the second region may be an outer region surrounding the chip mounting region. Alternatively, the first region of the protective layer may be a central region of a terminal region connected to an external board. And, the second region of the protective layer may be an outer region excluding the central region of the terminal region.

And, the protective layer includes a first opening and a second opening. The first opening has an opening width smaller than a width of the pad overlapping perpendicularly thereto, and the second opening has an opening width that is greater than a width of the pad that overlaps it vertically.

Additionally, the first region of the protective layer includes a plurality of first openings and at least one second opening that vertically overlap a plurality of first pads. And, a number of first openings formed in the first region of the protective layer is greater than a number of second openings formed in the first region of the protective layer. That is, the embodiment allows a total number of first openings in the first region to be greater than the total number of second openings in the first region based on a direction of stress applied to the first region, a degree of warpage of the circuit board, and a design of the first pads that overlap vertically with the first region. Accordingly, the embodiment can improve a bonding force between the first pad and the insulating layer while maintaining a bonding force between the first pad and the solder ball. Accordingly, the embodiment can improve the physical reliability of the circuit board. In addition, the embodiment allows the first opening to be formed in more than the second opening in the first region, so that the traces concentrated in the first region can be stably protected, and accordingly, damage to the trace from various factors can be prevented. Additionally, when an external board is bonded to a connection part, the embodiment can improve bonding between the circuit board and the external board. Additionally, when a chip is mounted on the connection part, the embodiment can improve the mount-ability of the chip and thus improve the product reliability of the circuit board.

Additionally, the second region of the protective layer includes at least one first opening and a plurality of second openings that vertically overlap the plurality of second pads. And, the number of second openings formed in the second region of the protective layer is greater than the number of first openings formed in the second region. That is, the embodiment allows the total number of second openings in the second region to be greater than the total number of first openings in the second region based on a direction of stress applied to the second region, a degree of warpage of the circuit board, and a design of the second pads that overlap vertically with the second region. Accordingly, the embodiment can improve the bonding force between the second pad and the insulating layer while maintaining the bonding force between the second pad and the connection part.

As described above, the embodiment may provide third to sixth openings having various combinations of the first opening and the second opening according to the design of the circuit pattern layer. For example, in an embodiment, a third opening may be provided including a third-first opening that is a combination of the first opening and the second-first opening, and a third-second opening that is a combination of the first opening and the second-second opening. Additionally, the embodiment may provide a fourth opening that is a combination of second-first opening and second-second opening. Additionally, the embodiment may provide a fifth opening that is a combination of the first opening and the second-first opening or the first opening and the second-second opening. Additionally, the embodiment may provide a sixth opening that is a combination of the first opening, second-first opening, and second-second opening. Accordingly, the embodiment can stably protect the trace, increase the bonding area between the pad and the connection part, and improve bonding strength between the pad and the insulating layer, depending on the design of the circuit pattern layer.

### DESCRIPTION OF DRAWINGS

FIG. 1A (a)-(b) are diagrams showing a circuit board according to a first comparative example.

FIG. 1B (a)-(b) are diagrams showing a circuit board according to a second comparative example.

FIG. 2A is a cross-sectional view illustrating a semiconductor package according to a first embodiment.

FIG. 2B is a cross-sectional view illustrating a semiconductor package according to a second embodiment.

FIG. 2C is a cross-sectional view illustrating a semiconductor package according to a third embodiment.

FIG. 2D is a cross-sectional view illustrating a semiconductor package according to a fourth embodiment.

FIG. 2E is a cross-sectional view illustrating a semiconductor package according to a fifth embodiment.

FIG. 2F is a cross-sectional view illustrating a semiconductor package according to a sixth embodiment.

FIG. 2G is a cross-sectional view illustrating a semiconductor package according to a seventh embodiment.

FIG. 3A is a cross-sectional view of a circuit board according to an embodiment.

FIG. 3B is a diagram for explaining a structure of a circuit pattern layer for each region of a circuit board according to an embodiment.

FIG. 3C is a diagram for explaining division conditions of a first region and a second region in a first protective layer.

FIG. 3D is a diagram for explaining a structure of openings for each region of the protective layer according to an embodiment.

FIG. 3E (a)-(b) are diagrams for explaining a first opening formed in a protective layer according to an embodiment.

FIG. 3F (a)-(b) are diagrams for explaining a second opening formed in the protective layer according to an embodiment.

FIG. 4A is a plan view of a circuit board including a third opening according to a second embodiment.

FIG. 4B (a)-(b) are cross-sectional views of the circuit board of FIG. 4A.

FIG. 5 (a)-(b) are diagrams for explaining a fourth opening according to a third embodiment.

FIG. 6A is a plan view of a circuit pattern layer to which a fifth opening will be applied according to an embodiment.

FIG. 6B (a)-(b) are diagrams showing a fifth opening according to a first embodiment.

FIG. 6C (a)-(b) are diagrams showing a fifth opening according to a second embodiment.

FIG. 7A (a)-(b) are top views of a circuit pattern layer and a protective layer according to an embodiment.

FIG. 7B (a)-(b) are cross-sectional views of FIG. 7A.

FIG. 8 is a diagram showing a first package substrate according to an embodiment.

FIG. 9 is a diagram showing a second package substrate according to an embodiment.

FIGS. 10A to 10G are diagrams showing a method of manufacturing the circuit board according to a first embodiment in order of processes.

### MODES OF THE INVENTION

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to the accompanying drawings.

### Comparative Example

Before describing the embodiment, a comparative example compared to the circuit board of the embodiment of the present application will be described.

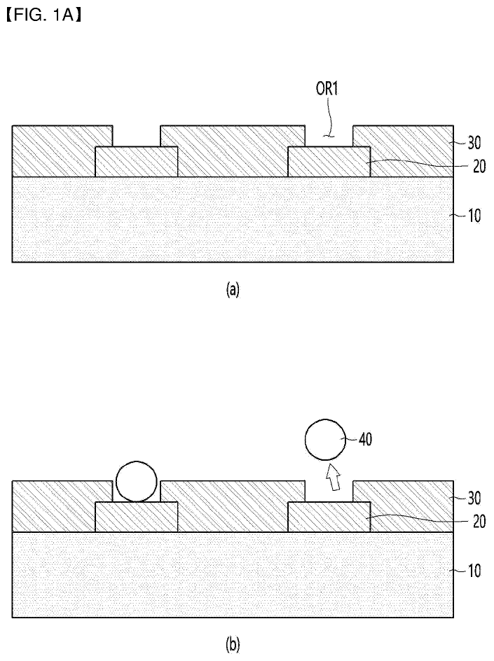

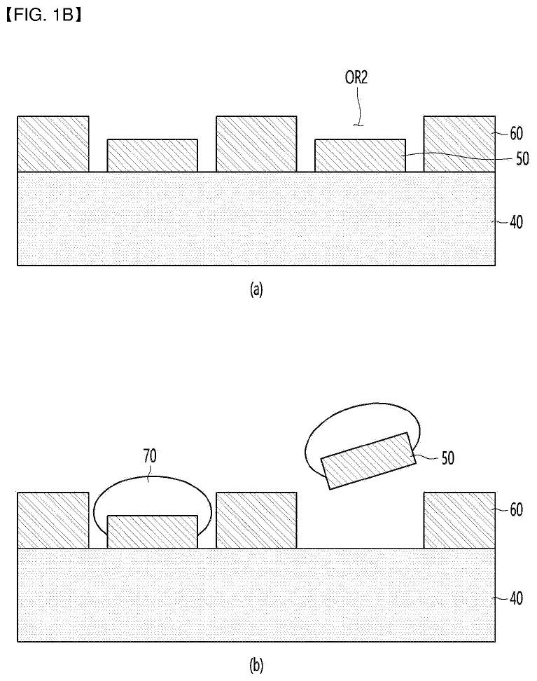

FIG. 1A is a diagram showing a circuit board according to a first comparative example, and FIG. 1B is a diagram showing a circuit board according to a second comparative example.

Specifically, FIG. 1A is a diagram showing a circuit board including a protective layer with an SMD type opening, and FIG. 1B is a diagram showing a circuit board including a protective layer with an NSMD type opening.

Referring to (a) of FIG. 1A, a circuit board of the first comparative example includes an insulating layer 10, a circuit pattern layer 20, and a protective layer 30.

An insulating layer 10 refers to an outermost insulating layer disposed as an outermost layer among a plurality of insulating layers of a circuit board having a plurality of layer structure.

A circuit pattern layer 20 is disposed on the outermost insulating layer. For example, the circuit pattern layer 20 refers to a circuit pattern layer disposed on the outermost layer among a plurality of circuit pattern layers of a circuit board having a plurality of layer structure.

A protective layer 30 is disposed on the outermost insulating layer. The protective layer 30 includes a first opening OR1 that vertically overlaps the circuit pattern layer 20.

The first opening OR1 has a width smaller than a width of the circuit pattern layer 20. For example, the first opening OR1 has an SMD type and vertically overlaps the circuit pattern layer 20.

Accordingly, a side surface of the circuit pattern layer 20 may be covered by the protective layer 30. For example, a side surface of the circuit pattern layer 20 does not horizontally overlap the first opening OR1 of the protective layer 30. Here, the meaning of not overlapping horizontally means that there is no region in which the side surface of the circuit pattern layer 20 is exposed through the first opening OR1 of the protective layer 30, or there is no region in contact with the protective layer 30 among the side surfaces of the circuit pattern layer 20.

Meanwhile, the circuit pattern layer 20 vertically overlapping the first opening OR1 may be referred to as a pad. The pad may be a terminal pad electrically connected to an external board (e.g., motherboard). Alternatively, the pad may be a mounting pad on which a semiconductor device is mounted.

Accordingly, as shown in (b) of FIG. 1A, a connection part 40 such as a solder ball is disposed within the first opening OR1.

At this time, the first opening OR1 has a width smaller than the width of the circuit pattern layer 20. And, the first opening OR1 vertically overlaps a portion of an upper surface of the circuit pattern layer 20. Accordingly, the connection part 40 contacts only a portion of an upper surface of the circuit pattern layer 20 that vertically overlaps the first opening OR1.

Accordingly, a bonding area between the connection part 40 and the circuit pattern layer 20 in the first comparative example is smaller than an area of an upper surface of the circuit pattern layer 20. Therefore, in the first comparative example, the bonding force between the connection part 40 and the circuit pattern layer 20 may decrease as the bonding area between the connection part 40 and the circuit pattern layer 20 is small. Accordingly, in the first comparative example, a reliability problem may occur in which the connection part 40 is separated from the circuit pattern layer 20 due to a decrease in the bonding strength between the circuit pattern layer 20 and the connection part 40.

Meanwhile, referring to (a) of FIG. 1B, the circuit board of the second comparative example includes an insulating layer 40, a circuit pattern layer 50, and a protective layer 60.

The protective layer 60 in the second comparative example includes a second opening OR2 that vertically overlaps the circuit pattern layer 50.

The second opening OR2 has a width greater than a width of the circuit pattern layer 50. For example, the second opening OR2 has an NSMD type. Accordingly, the second opening OR2 overlaps the circuit pattern layer 50 vertically and horizontally. Accordingly, upper and side surfaces of the circuit pattern layer 50 vertically overlapping the second opening OR2 do not contact the protective layer 60. Here, horizontally overlapping means that at least a part of the side surface of the circuit pattern layer 50 is exposed through the second opening OR2, or at least a part of the side surface of the circuit pattern layer 50 is not in contact with the protective layer.

Additionally, as shown in (b) of FIG. 1B, a connection part 70 such as a solder ball is disposed within the second opening OR2.

At this time, the second opening OR2 has a width greater than the width of the circuit pattern layer 50, and accordingly, the connection part 70 contacts not only the upper surface of the circuit pattern layer 50 but also the side surface. Accordingly, in the second comparative example, it is possible to secure bonding strength as the bonding area between the connection part and the circuit pattern layer increases compared to the first comparative example.

However, the circuit pattern layer 50 vertically overlapped with the second opening OR2 in the second comparative example is not protected by the protective layer 60. For example, an inner wall of the second opening OR2 is spaced apart from the circuit pattern layer 50 at a certain distance. Accordingly, in the second comparative example, when stress occurs on the circuit board, there is no protective layer 60 that holds the circuit pattern layer 50 vertically overlapping the second opening OR2, and accordingly, a reliability problem may occur in which the circuit pattern layer 50 is separated from the insulating layer 40 along with the connection part 70.

Additionally, the circuit pattern layer 50 includes a plurality of pads as described above. Additionally, the circuit pattern layer 50 includes traces, which are thin signal lines connecting the plurality of pads. Accordingly, when forming the NSMD type opening on the pad, at least a portion of the trace connected to the pad may also overlap the opening vertically and horizontally. Accordingly, in the second comparative example, there is a problem in that the traces connected to the pad are exposed to various risks during a process of manufacturing the circuit board. At this time, as the performance of products has improved, a line width of the trace has become smaller. Accordingly, when the trace vertically overlaps with the opening, a reliability problem may occur in which the trace is easily separated from the insulating layer.

As described above, the first and second comparative examples have different reliability problems depending on the type of opening of the protective layer.

That is, the SMD type has a reliability problem with low bonding strength between the connection part and the circuit pattern layer, and the NSMD type has a reliability problem with low bonding strength between the circuit pattern layer and the insulating layer.

At this time, the circuit board includes a region that requires bonding force between the connection part and the circuit pattern layer, and, differently, includes a region that requires bonding force between the circuit pattern layer and the insulating layer. In other words, the intensity or direction of stress applied varies depending on the region or location of the circuit board. Accordingly, the first region requires adhesion between the connection part and the circuit pattern layer, and the second region other than the first region requires adhesion between the insulating layer and the circuit pattern layer.

However, although both SMD-type openings and NSMD-type openings are applied to conventional circuit boards, the type of opening is not determined by considering the stress intensity or direction. Accordingly, when a plurality of SMD type openings are provided in the first region, there is a very high possibility that a reliability problem may occur where the connection part is separated from the circuit pattern layer. Additionally, when a plurality of NSMD type openings are provided in the second region, there is a very high possibility that a reliability problem may occur in which the circuit pattern layer is separated from the insulating layer.

Accordingly, the embodiment is intended to solve the problems of the comparative example above, and the type of opening of the protective layer is determined by considering the intensity or direction of stress applied depending on the region or location of the circuit board.

Additionally, in the embodiment, when a plurality of openings are formed in one pad, the types of the plurality of openings are applied differently. Through this, the embodiment makes it possible to improve the physical reliability of the pad by utilizing each advantage of a plurality of different types of openings for the single pad.

Additionally, in the embodiment, when one opening is formed in one pad, openings having partially different opening structures are provided for the one pad. Through this, the embodiment allows to further improve the physical reliability of the pad.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one chip. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, a circuit board in one embodiment may be a first board described below.

In addition, a circuit board in another embodiment may be a second board described below.

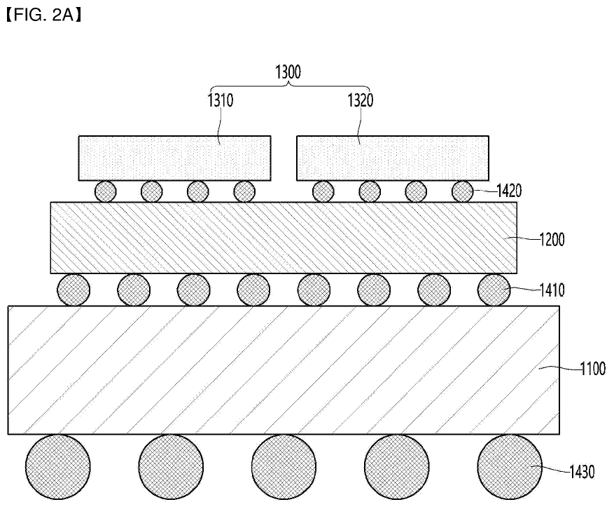

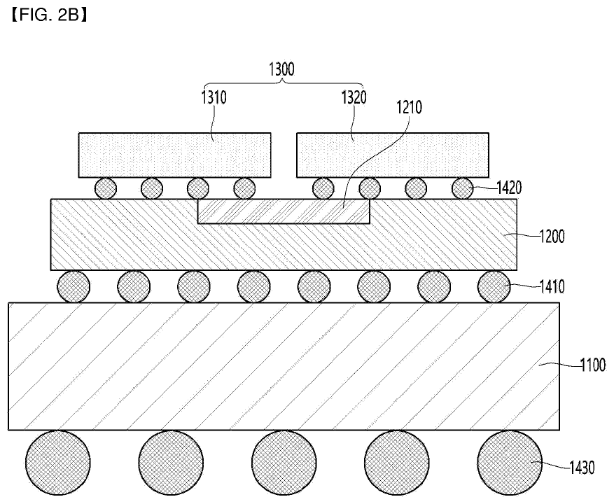

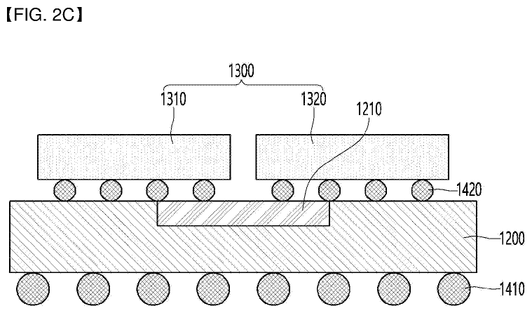

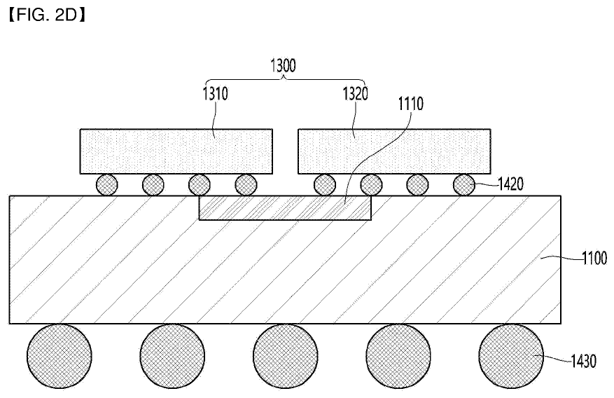

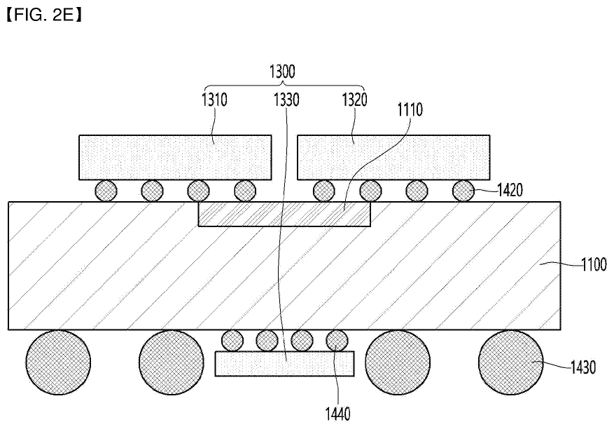

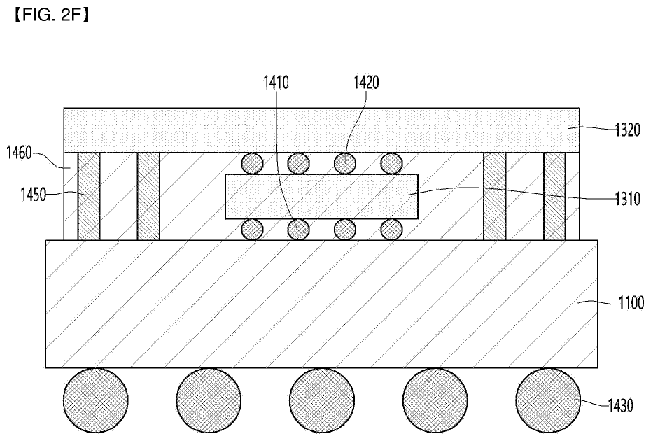

FIG. 2A is a cross-sectional view illustrating a semiconductor package according to a first embodiment, FIG. 2B is a cross-sectional view illustrating a semiconductor package according to a second embodiment, FIG. 2C is a cross-sectional view illustrating a semiconductor package according to a third embodiment, FIG. 2D is a cross-sectional view illustrating a semiconductor package according to a fourth embodiment, FIG. 2E is a cross-sectional view illustrating a semiconductor package according to a fifth embodiment, FIG. 2F is a cross-sectional view illustrating a semiconductor package according to a sixth embodiment, and FIG. 2G is a cross-sectional view illustrating a semiconductor package according to a seventh embodiment.

Referring to FIG. 2A, the semiconductor package according to the first embodiment may include a first circuit board 1100, a second circuit board 1200, and a semiconductor device 1300.

The first circuit board 1100 may mean a package substrate.

For example, the first circuit board 1100 may provide a space to which at least one external substrate is coupled. The external substrate may refer to a second circuit board 1200 coupled to the first circuit board 1100. Also, the external substrate may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer, and a through electrode passing through the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 2A illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one of the semiconductor device 1300 and the first circuit board 1100.

In one embodiment, the second circuit board 1200 may be an active interposer that functions as a semiconductor device. When the second circuit board 1200 functions as a semiconductor device, the semiconductor package of the embodiment may have a vertical stack structure on the first circuit board 1100 and function as a plurality of logic chips. Being able to have the functions of a logic chip may mean having the functions of an active device and a passive device. In the case of active devices, unlike passive devices, current and voltage characteristics may not be linear, and in the case of an active interposer, it can have the function of an active device. Additionally, the active interposer may function as a corresponding logic chip and perform a signal transmission function between the first circuit board 1100 and a second logic chip disposed on an upper portion of the active interposer.

According to another embodiment, the second circuit board 1200 may be a passive interposer. For example, the second circuit board 1200 may function as a signal relay between the semiconductor device 1300 and the first circuit board 1100, and may have passive device functions such as a resistor, capacitor, and inductor. For example, a number of terminals of the semiconductor device 1300 is gradually increasing due to 5G, Internet of Things (IoT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

the semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them. At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. and to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The TC bonding may refer to a method of directly coupling a plurality of components by applying heat and pressure to the first connection part 1410, the second connection part 1420, and the third connection part 1430.

In this case, at least one of the first circuit board 1100 and the second circuit board 1200 may include a protrusion provided on the electrode where the first connection part 1410, the second connection part 1420, and the third connection part 1430 are disposed, and protruding in an outward direction away from the insulating layer of the corresponding circuit board. The protrusion may protrude outward from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, the pitch of the terminals of the semiconductor device 1300 is becoming finer, as a result, a short circuit may occur between the plurality of second connection parts 1420 respectively connected to the plurality of terminals of the semiconductor device 1300 by a conductive adhesive such as solder. Accordingly, the embodiment may perform thermal compression bonding to reduce the volume of the second connection part 1420. Accordingly, the embodiment may include a protrusion in the electrode of the second circuit board 1200 on which the second connection part 1420 is disposed in order to secure position accuracy and diffusion prevention power to prevent the intermetallic compound (IMC) formed between a conductive adhesive such as solder and a protrusion from diffusing to the interposer and/or the circuit board.

Meanwhile, referring to FIG. 2B, the semiconductor package of the second embodiment may differ from the semiconductor package of the first embodiment in that the connecting member 1210 is disposed on the second circuit board 1200. The connecting member 1210 may be referred to as a bridge substrate. For example, the connecting member 1210 may include a redistribution layer. The connecting member 1210 may function to electrically connect a plurality of semiconductor devices to each other horizontally. For example, an area that a semiconductor device should have, is generally too large, and for this reason, the connecting member 1210 may include a redistribution layer. The semiconductor package and the semiconductor device have significant differences in a width and a spacing of their circuit patterns, and for this reason, a buffering role of the circuit pattern for electrical connection is necessary. The buffering role may mean having an intermediate size between the width or spacing of the circuit pattern of the semiconductor package and the width or spacing of the circuit pattern of the semiconductor device, and the redistribution layer may include a function that acts as a buffer.

In an embodiment, the connecting member 1210 may be a silicon bridge. That is, the connecting member 1210 may include a silicon substrate and a redistribution layer disposed on the silicon substrate.

In another embodiment, the connecting member 1210 may be an organic bridge. For example, the connecting member 1210 may include an organic material. For example, the connecting member 1210 may include an organic substrate including an organic material instead of the silicon substrate.

The connecting member 1210 may be embedded in the second circuit board 1200, but is not limited thereto. For example, the connecting member 1210 may be disposed on the second circuit board 1200 to have a protruding structure.

Also, the second circuit board 1200 may include a cavity, and the connecting member 1210 may be disposed in the cavity of the second circuit board 1200.

The connecting member 1210 may horizontally connect a plurality of semiconductor devices disposed on the second circuit board 1200.

Referring to FIG. 2C, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 2D, the semiconductor package according to the fourth embodiment may include a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment may function as a connection between the semiconductor device 1300 and the main board while functioning as a package substrate. To this end, the first circuit board 1100 may include a connecting member 1110 for connecting the plurality of semiconductor devices. The connecting member 1110 may be a silicon bridge or an organic material bridge connecting a plurality of semiconductor devices.

Referring to FIG. 2E, the semiconductor package of the fifth embodiment may further include a third semiconductor device 1330 compared to the semiconductor package of the fourth embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 2C.

Referring to FIG. 2F, the semiconductor package according to the sixth embodiment may include a first circuit board 1100. A first semiconductor device 1310 may be disposed on the first circuit board 1100. To this end, a first connection part 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connection part 1420 may be disposed on the first semiconductor device 1310 and the second semiconductor device 1320.

Accordingly, the second semiconductor device 1320 may be electrically connected to the first semiconductor device 1310 through the second connection part 1420.

That is, the second semiconductor device 1320 may be connected to the first circuit board 1100 through the conductive coupling portion 1450, and may be also connected to the first semiconductor device 1310 through the second connection part 1420.

In this case, the second semiconductor device 1320 may receive a power signal and/or an electrical power through the conductive coupling portion 1450. Also, the second semiconductor device 1320 may transmit and receive a communication signal to and from the first semiconductor device 1310 through the second connection part 1420.

The semiconductor package according to the sixth embodiment provides a power signal and/or an electrical power to the second semiconductor device 1320 through the conductive coupling portion 1450, and it may be possible to provide sufficient power for driving the second semiconductor device 1320 or to smoothly control power supply operation.

Accordingly, the embodiment may improve the driving characteristics of the second semiconductor device 1320. That is, the embodiment may solve the problem of insufficient power provided to the second semiconductor device 1320. Furthermore, in the embodiment, at least one of the power signal, the electrical power and the communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package substrates are stacked and may be disposed on the first substrate 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connection member 1410, the second connection member 1420, the first semiconductor device 1310, and the conductive coupling portion 1450.

Referring to FIG. 2G, the semiconductor package according to the seventh embodiment may include a first circuit board 1100, a first connection part 1410, a first connection part 1410, a semiconductor device 1300, and a third connection part 1430.

In this case, the semiconductor package of the seventh embodiment is different from the semiconductor package of the fourth embodiment in that the first circuit board 1100 includes a plurality of substrate layers while the connecting member 1110 is removed.

The first circuit board 1100 includes a plurality of substrate layers. For example, the first circuit board 1100 may include a first substrate layer 1100A corresponding to a package substrate and a second substrate layer 1100B corresponding to the connecting member.

In other words, the semiconductor package of the seventh embodiment may include a first substrate layer 1100A and a second substrate layer 1100B in which the first circuit board (package substrate, 1100) and the second circuit board (interposer, 1200) shown in FIG. 2A are integrally formed. The material of the insulating layer of the second substrate layer 1100B may be different from the material of the insulating layer of the first substrate layer 1100A. For example, the material of the insulating layer of the second substrate layer 1100B may include a photocurable material. For example, the second substrate layer 1100B may be a photo imageable dielectric (PID). In addition, since the second substrate layer 1100B includes a photocurable material, it is possible to miniaturize the electrode. Accordingly, in the seventh embodiment, the second substrate layer 1100B may be formed by sequentially stacking an insulating layer of a photo-curable material on the first substrate layer 1100A and forming a miniaturized electrode on the insulating layer of the photo-curable material. Through this, the second circuit board 1100B may be a redistribution layer including a miniaturized electrode and include a function to horizontally connect a plurality of semiconductor devices 1310 and 1320.

### —Circuit Board—

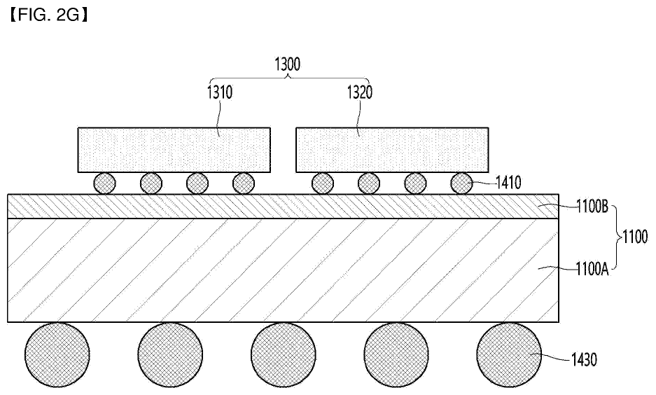

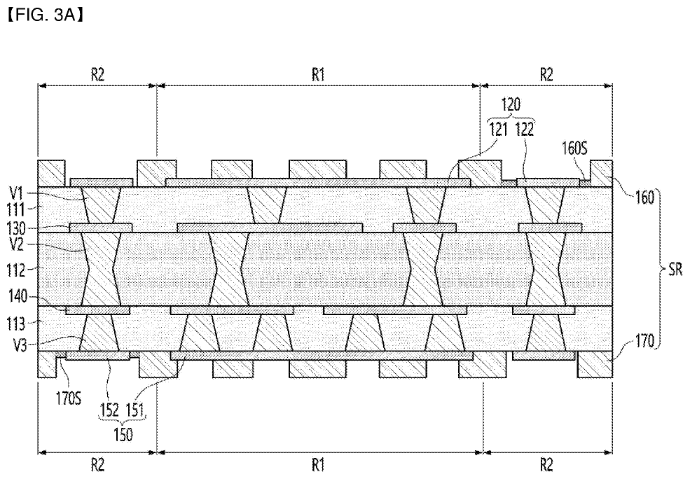

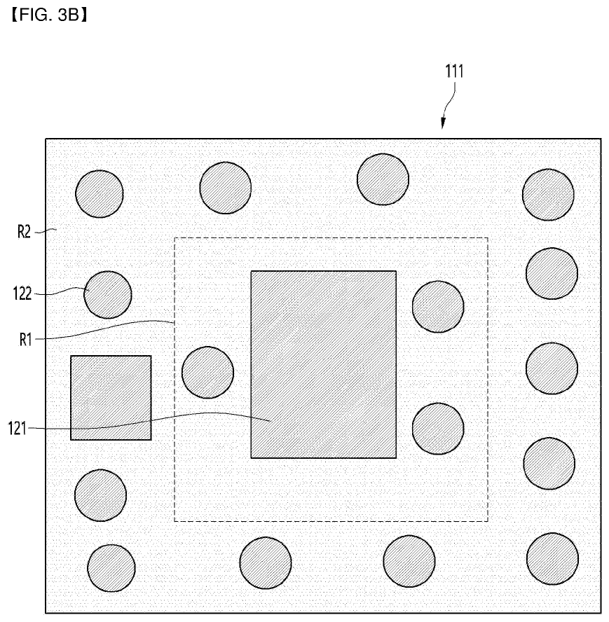

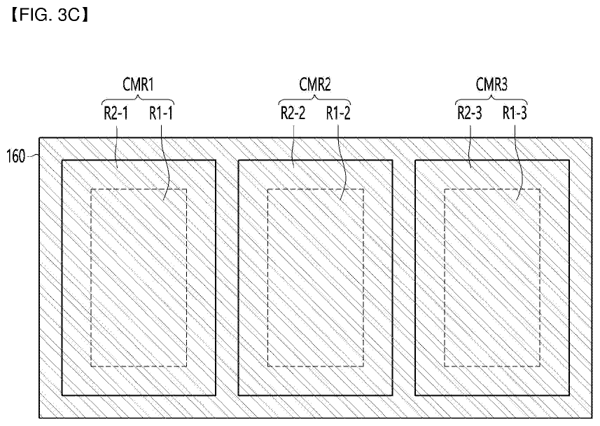

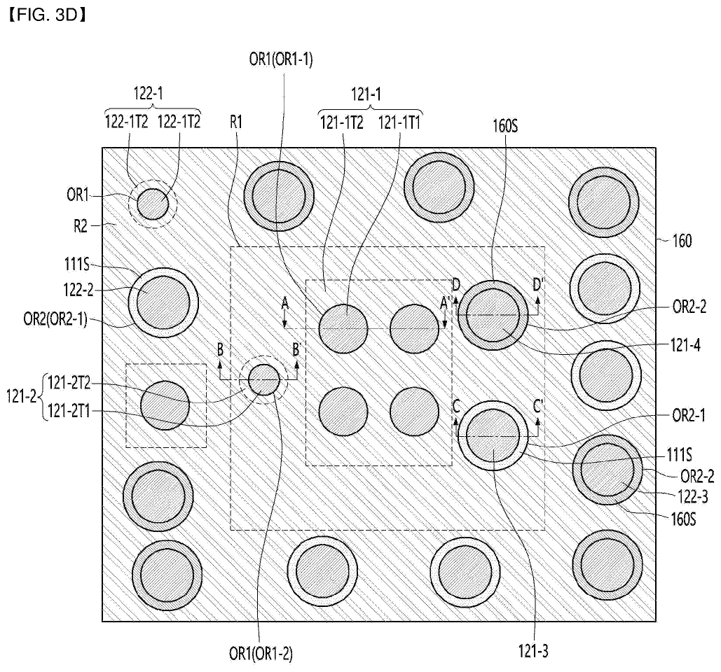

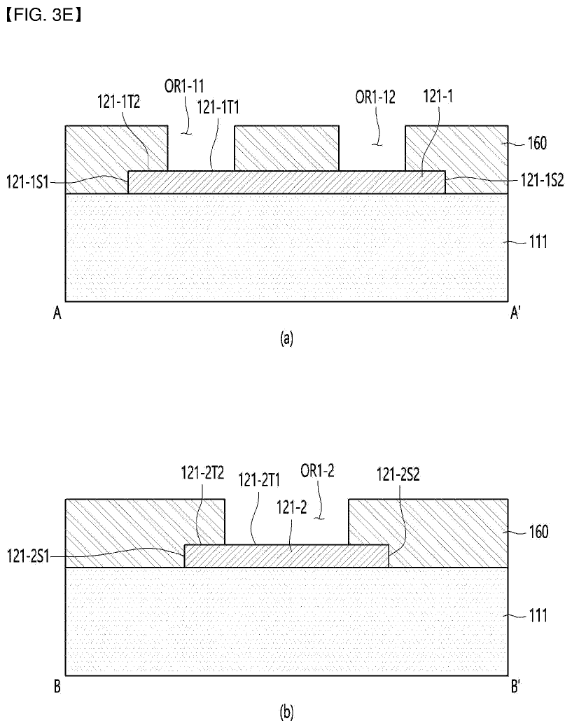

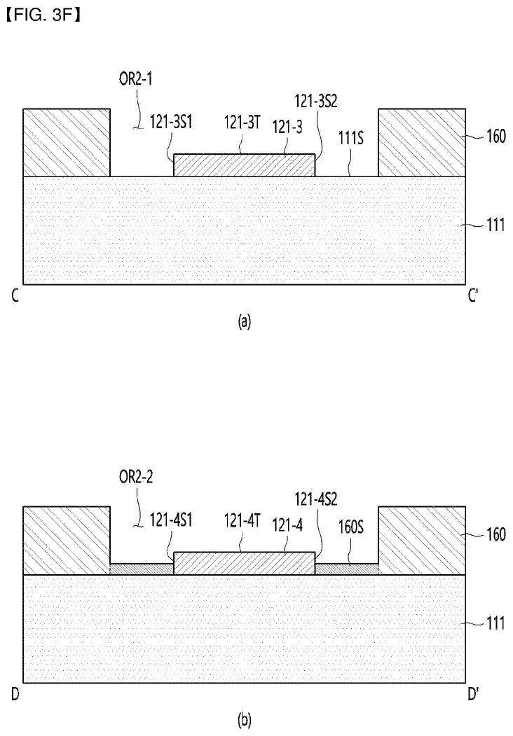

FIG. 3A is a cross-sectional view of a circuit board according to an embodiment. Hereinafter, an overall structure of a circuit board according to an embodiment of a present application will be described with reference to FIG. 3A.

Before describing the circuit board of the embodiment, the circuit board described below may refer to any one circuit board among a plurality of circuit boards included in the previously described semiconductor package.

For example, the circuit board of one embodiment described below includes the first circuit board 1100, the second circuit board 1200, and the connection member (or bridge board, 1110, 1210).

Referring to FIG. 3A, the circuit board includes an insulating layer 110, a circuit pattern layer, a through electrode, and a protective layer.

The insulating layer 110 may have a multiple layer structure. For example, an insulating layer 110 may include a first insulating layer 111, a second insulating layer 112, and a third insulating layer 113. At this time, the circuit board is shown in the drawing as having a three-layer structure based on the number of insulating layers, but it is not limited thereto. For example, the circuit board may have a structure (including single-layer structure) of two or less layers based on the number of insulating layers, or, alternatively, may have a structure of four or more layers based on the number of insulating layers.

For example, the first insulating layer 111 may be a first outermost insulating layer disposed at an first outermost side in a multi-layer structure. For example, the first insulating layer 111 may be an insulating layer disposed at an uppermost side of the circuit board. The second insulating layer 112 may be an inner insulating layer disposed at an inside of a multi-layered circuit board. The third insulating layer 113 may be a second outermost insulating layer disposed at the second outermost side in a multi-layer structure. For example, the third insulating layer 113 may be an insulating layer disposed at a lowermost side of the circuit board. In addition, in FIG. 3A, the inner insulating layer is shown as being composed of one layer, but the embodiment is not limited thereto. For example, if the circuit board has a layer structure of four or more layers, the inner insulating layer may have a layer structure of two or more layers.

The insulating layer 110 is a board equipped with an electric circuit whose wiring can be changed, and may include a print, a wiring board, and an insulating board made of an insulating material capable of forming circuit patterns on the surface.

For example, at least one of the insulating layer 110 may be rigid or flexible. For example, at least one of the insulating layer 110 may include glass or plastic. Specifically, the insulating layer 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire.

In addition, at least one of the insulating layer 110 may include an optically isotropic film. For example, at least one of the insulating layer 110 may include cyclic olefin copolymer (COC), cyclic olefin polymer (COP), optically isotropic PC, optically isotropic polymethylmethacrylate (PMMA), or the like.

In addition, at least one of the insulating layer 110 may be formed of a material including an inorganic filler and an insulating resin. For example, at least one of the insulating layer 330 may be formed of a resin containing reinforcing materials such as inorganic fillers such as silica and alumina together with a thermosetting resin such as an epoxy resin or a thermoplastic resin such as polyimide, specifically Ajinomoto Build-up Film (ABF), FR-4, Bismaleimide Triazine (BT), Photo Imageable Dielectric resin (PID), BT, or the like.

In addition, at least one of the insulating layers 110 may have a partially curved surface and be curved. That is, at least one of the insulating layers 110 is partially flat, and at least one of the insulating layers 110 may have a partially curved surface and be bent. In detail, at least one end of the insulating layer 110 may have a curved surface and be bent, or at least one end of the insulating layer 110 has a surface with random curvature and may be curved or bent.

A circuit pattern layer may be disposed on a surface of the insulating layer 110.

For example, a first circuit pattern layer 120 may be disposed on a first or upper surface of the first insulating layer 111. The first circuit pattern layer 120 may also be referred to as a first outermost circuit pattern layer disposed on a first outermost layer of a circuit board.

For example, a second circuit pattern layer 130 may be disposed between a second surface or lower surface of the first insulating layer 111 and a first surface or upper surface of the second insulating layer 112. For example, a third circuit pattern layer 140 may be disposed between a second surface or lower surface of the second insulating layer 112 and a first surface or upper surface of the third insulating layer 113. For example, a fourth circuit pattern layer 150 may be disposed on a second or lower surface of the third insulating layer 113.

The first circuit pattern layer 120 may be a circuit pattern layer disposed at a first outermost side or uppermost side of the circuit board. Additionally, the second circuit pattern layer 130 and the third circuit pattern layer 140 may be inner circuit pattern layers disposed inside the circuit board. Additionally, the fourth circuit pattern layer 150 may be a circuit pattern layer disposed at a second outermost side or lowermost side of the circuit board.

Meanwhile, when the circuit board has a single-layer structure based on the number of insulating layers, the second circuit pattern layer 130 and the third circuit pattern layer 140 may be omitted.

The first circuit pattern layer 120, the second circuit pattern layer 130, the third circuit pattern layer 140, and the fourth circuit pattern layer 150 is a wire that transmits electrical signals and may be formed of a metal material with high electrical conductivity. The first circuit pattern layer 120, the second circuit pattern layer 130, the third circuit pattern layer 140, and the fourth circuit pattern layer 150 may be formed of at least one metal material selected from among gold (Au), silver (Ag), platinum (Pt), titanium (Ti), tin (Sn), copper (Cu), and zinc (Zn). In addition, the first circuit pattern layer 120, the second circuit pattern layer 130, the third circuit pattern layer 140, and the fourth circuit pattern layer 150 may be formed of paste or solder paste including at least one metal material selected from among gold (Au), silver (Ag), platinum (Pt), titanium (Ti), tin (Sn), copper (Cu), and zinc (Zn), which are excellent in bonding force. Preferably, the first circuit pattern layer 120, the second circuit pattern layer 130, the third circuit pattern layer 140, and the fourth circuit pattern layer 150 may be formed of copper (Cu) having high electrical or thermal conductivity and a relatively low cost.

The first circuit pattern layer 120, the second circuit pattern layer 130, the third circuit pattern layer 140, and the fourth circuit pattern layer 150 can be formed using an additive process, a subtractive process, a modified semi additive process (MSAP) and a semi additive process (SAP), which is a typical circuit board manufacturing process, and a detailed description will be omitted here.

Meanwhile, each of the first to fourth circuit pattern layers 120, 130, 140, and 150 includes traces and pads.

The trace refers to a long line-shaped wiring that transmits electrical signals. Additionally, the pad may refer to a mounting pad on which components such as chips are mounted, a terminal pad or a core pad or BGA pad for connection to an external board, or a pad connected to a through electrode.

A through electrode may be formed in the insulating layer 110. The through electrode is formed to pass through the insulating layer 110, and thus can electrically connect circuit pattern layers arranged in different layers.

For example, a first through electrode V1 may be formed in the first insulating layer 111. The first through electrode V1 passes through the first insulating layer 111, and thus can electrically connect the first circuit pattern layer 120 and the second circuit pattern layer 130.

For example, a second through electrode V2 may be formed in the second insulating layer 112. The second through electrode V2 passes through the second insulating layer 112, and thus can electrically connect the second circuit pattern layer 130 and the third circuit pattern layer 140. At this time, the second insulating layer 112 may be a core layer. And, when the second insulating layer 112 is a core layer, the second through electrode V2 may have an hourglass shape. However, the embodiment is not limited thereto. For example, when the circuit board of the embodiment is a coreless board, the second through electrode V2 may have a same shape as the first through electrode V1 or the third through electrode V3.

For example, a third through electrode V3 may be formed in the third insulating layer 113. The third through electrode V3 passes through the third insulating layer 113, and thus can electrically connect the third circuit pattern layer 140 and the fourth circuit pattern layer 150.

The through electrodes V1, V2 and V3 as described above may be formed by filling the inside of a through hole formed in each insulating layer with a metal material. The through hole may be formed by any one of mechanical, laser, and chemical processing. When the via hole is formed by mechanical processing, a method such as milling, drilling and routing may be used, when the via hole is formed by laser processing, a method of UV or CO2 laser may be used, when the via hole is formed by chemical processing, a chemical including amino silane, ketones, or the like may be used.

When the through hole is formed, the through electrodes V1, V2, and V3 may be formed by filling the inside of the through hole with a conductive material. The metal material forming the through electrodes V1, V2, and V3 may be any one selected from among copper (Cu), silver (Ag), tin (Sn), gold (Au), nickel (Ni), and palladium (Pd). In addition, the conductive material may be filled by any one of electroless plating, electroplating, screen printing, sputtering, evaporation, ink jetting, and dispensing, or a combination thereof.

Meanwhile, a protective layer (SR) may be disposed on an outermost layer of a circuit board of an embodiment. For example, a first protective layer 160 may be disposed on the first outermost layer of the circuit board. For example, a second protective layer 170 may be disposed on the second outermost layer of the circuit board. The first outermost layer may refer to any one of uppermost and lowermost sides of the circuit board, and the second outermost layer may refer to the other of the uppermost and lowermost sides of the circuit board.

For example, the protective layer SR may include a first protective layer 160 disposed on an upper surface of the first insulating layer 111. For example, the protective layer SR may include a second protective layer 170 disposed on a lower surface of the third insulating layer 113.

At this time, when the circuit board has a single-layer structure, the circuit board may include only one insulating layer. In addition, the first protective layer 160 may be disposed on any one of the upper or lower surface of the one-layer insulating layer, and the second protective layer 170 may be disposed on the other of the upper and lower surfaces of the one-layer insulating layer.

The first protective layer 160 may include a plurality of openings. For example, the first protective layer 160 may include a plurality of openings that vertically overlap the first circuit pattern layer 120. The plurality of openings of the first protective layer 160 may vertically overlap different first circuit pattern layers 120. Alternatively, a plurality of openings of the first protective layer 160 may vertically overlap a specific first circuit pattern layer.

Additionally, the second protective layer 170 may include a plurality of openings. For example, the second protective layer 170 may include a plurality of openings that vertically overlap the fourth circuit pattern layer 150. The plurality of openings of the second protective layer 170 may vertically overlap different fourth circuit pattern layers 150. Alternatively, the plurality of openings of the second protective layer 170 may vertically overlap a specific fourth circuit pattern layer.

The first protective layer 160 and the second protective layer 170 as described above may include solder resist.

The first protective layer 160 may be divided into a plurality of regions. For example, the first protective layer 160 may include a first region R1 and a second region R2. The first region R1 of the first protective layer 160 may refer to a central region of an upper region of the first insulating layer 111. The second region R2 of the first protective layer 160 may be a region excluding the central region. For example, the second region R2 of the first protective layer 160 may be an outer region of the upper region of the first insulating layer 111.

At this time, the first region R1 and the second region R2 in the first protective layer 160 may be defined based on a chip mounting region. For example, a chip may be mounted on the first circuit pattern layer 120. Accordingly, the first region R1 of the first protective layer 160 may correspond to a chip mounting region where a chip is mounted. In addition, the second region R2 of the first protective layer 160 may be a region excluding the chip mounting region. For example, the second region R2 of the first protective layer 160 may be an outer region of the chip mounting region surrounding the chip mounting region.

Meanwhile, the second protective layer 170 may also be divided into a plurality of regions corresponding to the first protective layer 160. For example, the second protective layer 170 may include a first region R1 and a second region R2.

At this time, the first region R1 of the second protective layer 170 may vertically overlap with the first protective layer 160, or alternatively, may not overlap vertically. Additionally, the second region R2 of the second protective layer 170 may vertically overlap the first protective layer 160, or alternatively, may not vertically overlap the first protective layer 160. For example, at least a portion of the first region R1 of the second protective layer 170 vertically overlaps the first region R1 of the first protective layer 160, and the remaining portion of the first region R1 of the second protective layer 170 may vertically overlap the second region R2 of the first protective layer 160. This is because a region division condition in the first protective layer 160 and a region division condition in the second protective layer 170 are different from each other.

For example, the first region R1 and the second region R2 of the first protective layer 160 may be divided based on the chip mounting region as described above.

Unlike this, the first region R1 and the second region R2 of the second protective layer 170 may be divided based on a central region and an outer region of the second protective layer 170, rather than the chip mounting region. For example, a chip may not be mounted on the fourth circuit pattern layer 150. Accordingly, the first region R1 of the second protective layer 170 may mean a central region of an entire region of the second protective layer 170. Also, the second region R2 of the second protective layer 170 may be an outer region of the entire region of the second protective layer 170 excluding the central region of the second protective layer 170.

In the first embodiment, the opening formed in the protective layer (SR) may include a first opening (OR1, see FIGS. 3B to 3F) and a second opening (OR2, see FIGS. 3B to 3F).

The first opening OR1 and the second opening OR2 can be distinguished by a relationship between an opening width and a width of the pad.

For example, an opening width of the first opening OR1 may be smaller than the width of the pad. For example, the first opening OR1 may mean an SMD type opening. Accordingly, an entire region of a side surface of the pad that vertically overlaps the first opening OR1 may be covered by the protective layer. Additionally, at least a portion of an upper surface of the pad that vertically overlaps the first opening OR1 may be covered by the protective layer.

For example, an opening width of the second opening OR2 may be greater than a width of the pad. For example, the second opening OR2 may mean an opening other than the SMD type. Accordingly, at least a portion of a side surface of the pad that vertically overlaps the second opening OR2 may not be in contact with the protective layer. For example, at least a portion of the side surface of the pad that vertically overlaps the second opening OR2 may overlap horizontally with the second opening OR2. For example, at least a portion of the side surface of the pad that vertically overlaps the second opening OR2 may be spaced apart from an inner wall of the second opening OR2. Additionally, an entire region of an upper surface of the pad that vertically overlaps the second opening OR2 may vertically overlap the second opening OR2. Here, the horizontally overlapping may mean that at least some of the side surfaces of the pad directly face the second opening OR2, or that at least some of the side surfaces of said pad are exposed through the second opening OR2, or that at least some of the side surfaces of the pad are not covered by the protective layer. Hereinafter, the expressions “horizontally overlapping” or “not horizontally overlapping” shall be used in same sense as described above.

And, in an embodiment, a plurality of first openings OR1 and second openings OR2 may be formed in the first region R1 of the first protective layer 160. Additionally, a plurality of first openings OR1 and second openings OR2 may be formed in the second region R2 of the first protective layer 160.

At this time, in the embodiment, the number of second openings OR2 formed in the second region R2 of the first protective layer 160 is greater than the number of second openings OR2 formed in the first region R1 of the first protective layer 160.

For example, a first opening OR1 and a second opening OR2 may be formed in the first region R1 of the first protective layer 160. Additionally, a first opening OR1 and a second opening OR2 may be formed in the second region R2 of the first protective layer 160.

At this time, the number of first openings OR1 included in the first region R1 of the first protective layer 160 may be greater than the number of first openings OR1 included in the second region R2 of the first protective layer 160. In addition, the number of second openings OR2 included in the second region R2 of the first protective layer 160 may be greater than the number of second openings OR2 included in the first region R1 of the first protective layer 160.

In addition, the number of first openings OR1 included in the first region R1 of the first protective layer 160 may be greater than the number of second openings OR2 included in the first region R1 of the first protective layer 160. In addition, the number of second openings OR2 included in the second region R2 of the first protective layer 160 may be greater than the number of first openings OR1 included in the second region R2 of the first protective layer 160.

Specifically, the embodiment satisfies at least one of the four conditions below when forming the opening of the first protective layer 160.
(1) The number of first openings OR1 included in the first region R1 of the first protective layer 160 should be greater than the number of first openings OR1 included in the second region R2 of the first protective layer 160.
(2) The number of second openings OR2 included in the second region R2 of the first protective layer 160 should be greater than the number of second openings OR2 included in the first region R1.
(3) The number of first openings OR1 included in the first region R1 of the first protective layer 160 should be greater than the number of second openings OR2 included in the first region R1 of the first protective layer 160.
(4) The number of second openings OR2 included in the second region R2 of the first protective layer 160 should be greater than the number of first openings OR1 included in the second region R2 of the first protective layer 160.

In addition, if any one of the four conditions above is not satisfied, or if all four conditions are not satisfied, the physical reliability or electrical reliability of the circuit board may be reduced, and the product reliability of the circuit board may be reduced accordingly.

That is, the embodiment allows the first opening OR1 to be provided more intensively than the second opening OR2 in the first region R1 of the first protective layer 160 and allows the second opening OR2 to be provided more intensively than the first opening OR1 in the second region R2 of one protective layer 160.

And, if at least one of the four conditions above is not satisfied, or if all four conditions are not satisfied, the traces of the first circuit pattern layer 120 in the first region R1 of the first protective layer 160 may not be stably protected, as a result, the physical reliability of the trace may be reduced. For example, the first region R1 of the first protective layer 160 corresponds to the chip mounting region. Accordingly, the first region R1 of the first protective layer 160 includes a pad for chip mounting and a trace connected to the pad. At this time, if the number of second openings OR2 increases in the first region R1 of the first protective layer 160, the trace may not be reliably protected. Furthermore, the trace is a fine pattern, and therefore damage may occur by various factors during the manufacturing process.

Furthermore, in a typical circuit board, stress occurs concentrated in the outer region of the board based on the plane, and as a result, deformation in the outer region of the circuit board may become severe. For example, warpage of a circuit board occurs due to differences in coefficient of thermal expansion (CTE) between each layer (e.g., an insulating layer and a circuit pattern layer) constituting the circuit board. The warpage of the circuit board may occur in a U shape or n shape. Through this, the warpage in the central region of the circuit board may be insufficient compared to the warpage in the outer region of the circuit board.

Accordingly, the warpage degree of the first region R1 of the first protective layer 160 may be smaller than the warpage degree of the second region R2 of the first protective layer 160. In addition, in the first region R1 of the first protective layer 160, the stress in a horizontal direction (++) appears greater than the stress in a vertical direction (11). Through this, in the first region R1 of the first protective layer 160, the bonding force between the pad of the first circuit pattern layer and the first insulating layer 111 may be more important than the bonding force between the pad of the first circuit pattern layer 120 and the solder ball (connection part). Accordingly, the embodiment allows the number of first openings OR1 in the first region R1 of the first protective layer 160 to be greater than the number of second openings OR2 in order to improve the adhesion between the pad of the first circuit pattern layer and the first insulating layer 111 in the first region R1.

In addition, a large-area pad of the first circuit pattern layer 120 may be mainly disposed on the first insulating layer 111 that vertically overlaps the first region R1 of the first protective layer 160. The large-area pad may refer to a pad that is commonly connected to a plurality of terminals included in one chip. Accordingly, a plurality of first openings OR1 of the first protective layer 160 may be formed on the large-area pad. At this time, there is no significant limitation on the opening width of the first opening OR1 formed on the large-area pad. For example, a large-area pad is disposed in the first region R1 of the first protective layer 160, so that the opening width of the first opening OR1 can be increased. Accordingly, even if the first opening OR1 is formed in the first region R1 of the first protective layer 160, it can ensure bonding strength between the pad of the first circuit pattern layer 120 and a connection part such as a solder ball.

Accordingly, in the embodiment, the number of first openings OR1 in the first region R1 of the first protective layer 160 is greater than the number of second openings OR2.

Meanwhile, a plurality of first openings OR1 and second openings OR2 may be formed in the second region R2 of the first protective layer 160. The number of second openings OR2 in the second region R2 of the first protective layer 160 should be greater than the number of second openings OR2 in the first region R1 of the first protective layer 160.

Additionally, if at least one of the four conditions above is not satisfied, or if all four conditions are not satisfied, the bonding force between the first circuit pattern layer 120 and the connection part in the second region R2 of the first protective layer 160 is reduced, and accordingly, a problem may occur in which the connection part is separated from the first circuit pattern layer.

Additionally, as described above, stress occurs concentrated in the outer region of the circuit board based on the plane of the circuit board. In addition, the coefficients of thermal expansion of each layer constituting the circuit board are different from each other, as a result, a warpage in the shape of a U or n shape occurs. Accordingly, the warpage degree of the outer region of the circuit board may be greater than the warpage degree of the central region of the circuit board.

Accordingly, the warpage degree of the second region R2 of the first protective layer 160 may be greater than the warpage degree of the first region R1 of the first protective layer 160. And, in the second region R2 of the first protective layer 160, the stress occurring in the vertical direction (14) appears to be greater than the stress occurring in the horizontal direction (+). Accordingly, in the second region R2 of the first protective layer 160, the bonding force between the first circuit pattern layer 120 and the connection part is more important than the bonding force between the first insulating layer 111 and the first circuit pattern layer 120.

Additionally, an island pad of the first circuit pattern layer 120 may be disposed on the first insulating layer 111 that vertically overlaps the second region R2 of the first protective layer 160. The island pad refers to a pad formed independently and not directly connected to other pads or traces. And, when forming the first opening OR1 on the island pad, since the width of the first opening OR1 must be smaller than that of the island pad, there are significant restrictions on the opening width. Accordingly, if the number of first openings OR1 in the second region R2 of the first protective layer 160 is greater than a reference number, the bonding force between the first circuit pattern layer 120 and the connection part in the second region R2 is reduced, and accordingly, a problem in which the connection part is separated from the first circuit pattern layer 120 may occur.

Meanwhile, the number of first openings OR1 and second openings OR2 in the first region R1 and the second region R2 of the second protective layer 170 can be controlled to correspond to the first region R1 and the second region R2 of the first protective layer 160.

For example, the number of first openings OR1 in the first region R1 of the second protective layer 170 should be greater than the number of second openings OR2 in the first region R1 of the second protective layer 170.

In addition, the number of second openings OR2 in the second region R2 of the second protective layer 170 should be greater than the number of first openings OR1 in the second region R2 of the second protective layer 170.

In addition, the number of second openings OR2 in the second region R2 of the second protective layer 170 should be greater than the number of second openings OR2 in the first region R1 of the second protective layer 170.

In addition, the number of first openings OR1 in the first region R1 of the second protective layer 170 should be greater than the number of first openings OR1 in the second region R2 of the second protective layer 170.

Hereinafter, the region of the first protective layer 160 and the second protective layer 170 according to the embodiment and the shape of the opening according to the region will be described in detail.

At this time, in the embodiment, the first protective layer 160 and the second protective layer 170 only have different conditions for distinguishing regions, and a structure of the opening in each region may be substantially the same.

Accordingly, hereinafter, the structure of the opening for the first region R1 and the second region R2 will be described based on the first protective layer 160.

However, the structure described below can be equally applied to both the first protective layer 160 and the second protective layer 170.

Accordingly, hereinafter, the first protective layer 160 is referred to as a protective layer 160, the first insulating layer 111 is referred to as an insulating layer 111 and the first circuit pattern layer 120 is referred to as a circuit pattern layer 120.

However, the protective layer 160 described below may refer to any one of the first protective layer 160 and the second protective layer 170. Additionally, the insulating layer 111 described below may refer to any one of the first insulating layer 111 disposed on the first outermost layer and the third insulating layer 113 disposed on the second outermost layer. In addition, the circuit pattern layer 120 described below may refer to the first circuit pattern layer 120 disposed on the first insulating layer 111, and alternatively, the circuit pattern layer 120 described below may refer to the fourth circuit pattern layer 150 disposed on the third insulating layer 113.

FIG. 3B is a diagram for explaining a structure of a circuit pattern layer for each region of a circuit board according to an embodiment, FIG. 3C is a diagram for explaining division conditions of a first region and a second region in a first protective layer, FIG. 3D is a diagram for explaining a structure of openings for each region of the protective layer according to an embodiment, FIG. 3E is a diagram for explaining a first opening formed in a protective layer according to an embodiment, and FIG. 3F is a diagram for explaining a second opening formed in the protective layer according to an embodiment.

Referring to FIG. 3B, an upper region of the insulating layer 111 may be divided into a first region R1 and a second region R2. For example, the first region R1 may mean a first region R1 of the protective layer 160. The second region R2 may refer to a second region of the protective layer 160.

Additionally, a plurality of first pads 121 of the circuit pattern layer 120 are disposed in the first region R1 of the insulating layer 111. For example, a plurality of second pads 122 of the circuit pattern layer 120 are disposed in the second region R2 of the insulating layer 111.

At this time, the first pad 121 disposed in the first region R1 may be a mounting pad on which a chip is mounted. That is, when the first region R1 is the first region R1 of the first protective layer 160, the first pad 121 may mean a chip mounting pad disposed in a chip mounting region. In addition, when the first region R1 is the first region R1 of the second protective layer 170, the first pad 121 may refer to a terminal pad disposed in a central region of a lower surface of the third insulating layer 113.

Meanwhile, the second pad 122 disposed in the second region R2 may refer to pads disposed around the first region R1. The second pad 122 is connected to the first pad 121 and may function to transmit an electrical signal to an outside. Alternatively, the second pad 122 may include heat dissipation pads for a heat dissipation function.

At this time, as described above, a plurality of first pads 121 are disposed in the first region R1, and a plurality of second pads 122 are disposed in the second region R2.

In addition, the protective layer 160 in the first region R1 includes a plurality of openings that each vertically overlap the plurality of first pads 121.

Additionally, the protective layer 160 in the second region R2 includes a plurality of openings that each vertically overlap the plurality of second pads 122.

Hereinafter, the structures of the first opening OR1 and the second opening OR2 will be described.

First, when the first region R1 and the second region R2 are chip mounting regions, the conditions for dividing the first region R1 and the second region R2 on the plane of the circuit board are as follows.

Referring to FIG. 3C, one chip may be mounted on the circuit board, and alternatively, a plurality of chips may be mounted on the circuit board.

At this time, when one chip is mounted on the circuit board, one first region R1 and one second region R2 may be provided. Unlike this, when a plurality of chips are mounted on the circuit board, a plurality of first regions R1 and a plurality of second regions R2 may be provided. For example, when three chips are mounted on the circuit board, the first region R1 may include three first regions corresponding to each of the three chips, and the second region R2 may also include three second regions corresponding to the three first regions.

For example, when three chips are mounted on a circuit board, the circuit board includes a first mounting region CMR1 corresponding to the region in which the first chip is mounted, a second mounting region CMR2 corresponding to the region in which the second chip is mounted, and a third mounting region CMR3 corresponding to the region in which the third chip is mounted.

In addition, the first mounting region CMR1 may include a first-first region R1-1 corresponding to a region vertically overlapping with the first chip, and a second-first region R2-1 outside the first-first region R1-1.

In addition, the second mounting region CMR2 may include a first-second region R1-2 corresponding to a region vertically overlapping with the second chip and a second-second region R2-2 outside the first-second region R1-2.

In addition, the third mounting region CMR3 may include a first-third region R1-3 corresponding to a region vertically overlapping with the third chip and a second-third region R2-3 outside the first-third region R1-3.

In addition, the first region R1 described below may refer to the first-first region R1-1 in the first mounting region CMR1, the first-second region R1-2 in the second mounting region CMR2, and the first-third region R1-3 in the third mounting region CMR3.

In addition, the second region R2 described below may refer to the second-first region R2-1 in the first mounting region CMR1, the second-second region R2-2 in the second mounting region CMR2, and the second-third region R2-3 in the third mounting region CMR3.

In contrast, the first region R1 described below may refer to the central region in the entire region of the circuit board based on the second protective layer 170, and the second region R2 may refer to the remaining regions excluding the central region based on the second protective layer 170, for example, the outer region around the central region.

Meanwhile, as shown in FIG. 3D, a protective layer 160 is disposed on the insulating layer 111. In addition, the protective layer 160 includes a first region R1 and a second region R2.

In addition, a plurality of first openings OR1 and second openings OR2 are formed in the first region R1 of the protective layer 160, and a plurality of first openings OR1 and a plurality of second openings OR2 may be formed in the second region R2 of the protective layer 160. In addition, the number of first openings OR1 in the first region R1 is greater than the number of second openings OR2 in the first region R1, and the number of second openings OR2 in the second region R2 is greater than the number of first openings OR1 in the second region R2.

The first opening OR1 and the second opening OR2 are described as follows.

The first opening OR1 can be divided into first-first opening OR1-1 and first-second opening OR1-2 depending on whether a single opening or multiple openings are formed on one pad.

Meanwhile, the following description will be based on the first opening OR1 and the second opening OR2 formed in the first region R1 of the protective layer 160. However, the first opening OR1 and the second opening OR2 corresponding to the first opening OR1 and the second opening OR2 formed in the first region R1 of the protective layer 160 may be formed in the second region R2 of the protective layer 160. However, the number of first openings OR1 and the number of second openings OR2 formed in each region may be different.

Referring to FIG. 3E, a first opening OR1 may be formed in the protective layer 160. (a) of FIG. 3E is a cross-sectional view taken along a A-A′ direction of FIG. 3D, and (b) of FIG. 3E is a cross-sectional view taken along a B-B′ direction of FIG. 3D.

Referring to FIGS. 3D and 3E, the first opening OR1 can be divided into a first-first opening OR1-1 and a first-second opening OR1-2.

The first-first opening OR1-1 and first-second opening OR1-2 are same in that it is formed to cover an edge region of an upper surface of the first pad 121 and a side surface of the first pad 121 while having an opening width smaller than the width of the first pad 121 that vertically overlaps it.

However, the first-first opening OR1-1 and first-second opening OR1-2 can be distinguished depending on whether a plurality of first openings OR1 are formed on one first pad 121 or one first opening OR1 is formed on one first pad 121.

For example, the first-first opening OR1-1 may have a structure in which a plurality of first openings OR1 are formed on one pad and spaced apart in the longitudinal or width direction. For example, the first-second opening OR1-2 may have a structure in which one first opening OR1 is formed on one pad.

However, hereinafter, the first opening OR1 will be described as being divided into the first-first opening OR1-1 and the first-second opening OR1-2 for convenience of explanation.

As shown in (a) of FIG. 3E, the first-first opening OR1-1 may be formed on the first-first pad 121-1. The first-first pad 121-1 may be a large-area pad. For example, the first-first pad 121-1 may refer to a pad commonly connected to a plurality of terminals of a chip. As an example, the first-first pad 121-1 may be a ground pad. As another example, the first-first pad 121-1 may be a heat dissipation pad. However, the embodiment is not limited thereto. For example, when the first-first pad 121-1 refers to the fourth circuit pattern layer 150 disposed in the first region R1 of the second protective layer 170, the first-first pad 121-1 may refer to a pad commonly connected to terminals of a plurality of external boards.

The first region R1 of the protective layer 160 may include a plurality of unit openings that overlap vertically with the first-first pad 121-1 and are spaced apart in the longitudinal or width direction.

Accordingly, an upper surface of the first-first pad 121-1 may include a plurality of first upper surfaces 121-1T1 that vertically overlap each of the plurality of unit openings OR1-11 and OR1-12.

In addition, the upper surface of the first-first pad 121-1 may include a second upper surface 121-1T2 that does not vertically overlap the plurality of unit openings OR1-11 and OR1-12 and is covered with the first region R1 of the protective layer 160.

The first upper surface 121-1T1 does not vertically overlap each of the plurality of unit openings OR1-11 and OR1-12 and is not partially covered by the first region R1 of the protective layer 160. Accordingly, the first-first pad 121-1 may include a plurality of exposed regions corresponding to the first upper surface 121-1T1. The plurality of exposed regions of the first-first pad 121-1 may be a connection arrangement region where a chip is mounted or a connection such as a solder ball for connection to an external board is disposed.

Meanwhile, the first-first opening OR1-1 including a plurality of unit openings OR1-11 and OR1-12 is not provided on the first-first pad 121-1, and accordingly, a side surface of the first-first pad 121-1 may be covered with the first region R1 of the protective layer 160. For example, the first-first pad 121-1 may include a first side surface 121-1S1 and a second side surface 121-S2 facing each other. In addition, the first side surface 121-1S1 and the second side surface 121-S2 of the first-first pad 121-1 may be covered with the first region R1 of the protective layer 160.

Meanwhile, when the first region R1 of the protective layer 160 includes the first-first opening OR1-1, the number of first openings OR1 in the first region R1 may include the total number of a plurality of unit openings OR1-11 and OR1-12 constituting the first-first opening OR1-1.

That is, one unit opening may mean one first opening OR1. That is, when there are three unit openings that overlap vertically with the first-first pad 121-1, the first-first pad 121-1 may vertically overlap three first openings OR1 spaced apart in the longitudinal or width direction.

Additionally, as shown in (b) of FIG. 3E, the first opening OR1 includes the first-second opening OR1-2. Additionally, the first pad 121 of the circuit pattern layer 120 may include a first-second pad 121-2 that vertically overlaps the first-second opening OR1-2.

Also, the first-second pad 121-2 may vertically overlap one first opening OR1. For example, the first-second pad 121-2 may vertically overlap the first-second opening OR1-2.

The first-second opening OR1-2 may partially overlap an upper surface of the first-second pad 121-2. For example, the upper surface of the first-second pad 121-2 may include a first upper surface 121-2T1 that vertically overlaps the first-second opening OR1-2. Additionally, the first upper surface 121-2T1 may be a central region of the upper surface of the first-second pad 121-2. Additionally, an upper surface of the first-second pad 121-2 may include a second upper surface 121-2T2 that does not vertically overlap the first-second opening OR1-2. The second upper surface 121-2T2 may be an outer region excluding the first upper surface 121-2T1 of the first-second pad 121-2.

Additionally, a side surface of the first-second pad 121-2 may be covered with the first region R1 of the protective layer 160. For example, the first-second pad 121-2 vertically overlaps the first-second opening OR1-2 of the first opening OR1, and accordingly, the side surface of the first-second pad 121-2 may directly contact the first region R1 of the protective layer 160. For example, the first-second pad 121-2 may include a first side surface 121-2S1 and a second side surface 121-2S2 that are opposite to each other. In addition, the first side surface 121-2S1 and the second side surface 121-2S2 of the first-second pad 121-2 may be covered with the first region R1 of the protective layer 160. Preferably, an entire region of the side surface of the first-second pad 121-2 may be covered with the first region R1 of the protective layer 160.

Meanwhile, the first opening OR1 formed in the second region R2 of the protective layer 160 may also have a shape corresponding to the first opening OR1 formed in the first region R1. For example, the second region R2 of the protective layer 160 may include only the first-second opening OR1-2 of the first opening OR1. However, the embodiment is not limited thereto, and a first-first opening OR1-1 including a plurality of unit openings may be formed in the second region R2 of the protective layer 160.

Also, the first opening OR1 formed in the second region R2 of the protective layer 160 may vertically overlap the second-first pad 122-1. For example, the second-first pad 122-1 may include a first upper surface 122-1T1 vertically overlapping with the first opening OR1 formed in the second region R2 of the protective layer 160 and a second upper surface 122-1T2 covered with the second region R2 of the protective layer 160.

Meanwhile, referring to FIG. 3F, a second opening OR2 may be formed in the protective layer 160. (a) of FIG. 3F is a cross-sectional view taken along a C-C′ direction of FIG. 3D, and (b) of FIG. 3F is a cross-sectional view taken along a D-D′ direction of FIG. 3D.

Referring to FIGS. 3D and 3F, the second opening OR2 may include a second-first opening OR2-1 and a second-second opening OR2-2.

The second-first opening OR2-1 and second-second opening OR2-2 have the same structure in that each opening has an opening width larger than the width of the pad that overlaps vertically. However, the second-first opening OR2-1 and the second-second opening OR2-2 can be distinguished depending on whether the entire side surface of the pad that overlaps each opening vertically is exposed or whether the side surface of the pad is partially exposed.

For example, second-first opening OR2-1 and second-second opening OR2-2 can be distinguished depending on whether it horizontally overlaps with the entire region of the side surface of the first pad or whether it horizontally overlaps with some regions of the side surface of the first pad.

The second-first opening OR2-1 may vertically overlap the first-third pad 121-3. At this time, the second-first opening OR2-1 may horizontally overlap the first-third pad 121-3. Preferably, the second-first opening OR2-1 may horizontally overlap the entire region of the side surface of the first-third pad 121-3. For example, in the first region R1 of the protective layer 160, a bottom surface of the second-first opening OR2-1 has a height corresponding to a lower surface of the first-third pad 121-3 or the upper surface of the insulating layer 111.

Accordingly, the entire region of the side surface of the first-third pad 121-3 may not contact the first region R1 of the protective layer 160.

For example, the entire region 121-3T of the upper surface of the first-third pad 121-3 may vertically overlap with the second-first opening OR2-1 formed in the first region R1 of the protective layer 160. Additionally, the entire region 121-3S1 and 121-3S2 of the side surface of the first-third pad 121-3 may horizontally overlap the second-first opening OR2-1.

Accordingly, the insulating layer 111 may include a non-overlapping region 111S that does not vertically overlap the circuit pattern layer 120 and the protective layer 160. For example, the non-overlapping region 111S of the insulating layer 111 may not vertically overlap the first-third pad 121-3 and the protective layer 160 of the circuit pattern layer 120, but may vertically overlap the second-first opening OR2-1.

Correspondingly, the second-first opening OR2-1 may be formed in the second region R2 of the protective layer 160. For example, the second-first opening OR2-1 formed in the second region R2 of the protective layer 160 may vertically overlap the second-second pad 122-2. Also, the entire region of the upper surface of the second-second pad 122-2 may vertically overlap the second-first opening OR2-1 formed in the second region R2. Additionally, the entire region of the side surface of the second-second pad 122-2 may horizontally overlap the second-first opening OR2-1 formed in the second region R2.

Meanwhile, the second-second opening OR2-2 in the first region R1 of the protective layer 160 may be disposed on the first-fourth pad 121-4. At this time, the second-second opening OR2-2 may overlap horizontally with the first-fourth pad 121-4. Preferably, the second-second opening OR2-2 may horizontally overlap a portion of the side surface of the first-fourth pad 121-4.

For example, in the first region R1 of the protective layer 160, the bottom surface of the second-second opening OR2-2 may be located lower than the upper surface of the first-fourth pad 121-4 and higher than the lower surface of the first-fourth pad 121-4.

Accordingly, some regions of the side surface of the first-fourth pad 121-4 may contact the first region R1 of the protective layer 160.

For example, the entire region 121-4T of the upper surface of the first-fourth pad 121-4 may vertically overlap the second-second opening OR2-2 formed in the first region R1 of the protective layer 160.

Additionally, some regions 121-4S1 and 121-4S2 of the side surface of the first-fourth pad 121-4 may overlap horizontally with the second-second opening OR2-2. To explain this differently, the remaining region of the side surface of the first-fourth pad 121-4 may directly contact the first region R1 of the protective layer 160 and be covered with the first region R1 of the protective layer 160.

Accordingly, the first region R1 of the protective layer 160 may include a supporting portion 160S disposed adjacent to the first-fourth pad 121-4 and partially covering the side surface of the first-fourth pad 121-4. The upper surface of the support portion 160S of the first region R1 of the protective layer 160 can correspond to the bottom surface of the second-second opening OR2-2. And, the upper surface of the supporting portion 160S is located lower than the upper surface of the first-fourth pad 121-4 and may directly contact a portion of the side surface of the first-fourth pad 121-4.

In the embodiment, in a region in which the second-second opening OR2-2 is formed, a part of the side surface of the first-fourth pad 121-4, which vertically overlaps the second-second opening OR2-2, may be supported using the support portion 160S1 of the protective layer 160. Accordingly, the embodiment can improve the adhesion between the first-fourth pad 121-4 and the connection part by using the second-second opening OR2-2 having the above structure. In addition, the embodiment can improve the adhesion between the first-fourth pad 121-4 and the insulating layer 111.

Meanwhile, correspondingly, the second-second opening OR2-2 may be formed in the second region R2 of the protective layer 160. For example, the second-second opening OR2-2 formed in the second region R2 of the protective layer 160 may vertically overlap the second-third pad 122-3. Also, the entire region of the upper surface of the second-third pad 122-3 may vertically overlap the second-second opening OR2-2 formed in the second region R2. In addition, some regions of the side surface of the second-third pad 122-3 are covered with the supporting portion 160S1 of the second region R2 of the protective layer 160, and the remaining portion of the second-third pad 122-3 may overlap horizontally with the second-second opening OR2-2.

As described above, the embodiment includes an insulating layer, a circuit pattern layer disposed on the insulating layer, and a protective layer partially disposed on the insulating layer and the circuit pattern layer.

At this time, the protective layer may be divided into a first region and a second region. The first region of the protective layer may correspond to a chip mounting region where a chip is mounted, and the second region may be an outer region surrounding the chip mounting region. Alternatively, the first region of the protective layer may be a central region of a terminal region connected to an external board. And, the second region of the protective layer may be an outer region excluding the central region of the terminal region.

And, the protective layer includes a first opening and a second opening. The first opening has an opening width smaller than a width of the pad overlapping perpendicularly thereto, and the second opening has an opening width that is greater than a width of the pad that overlaps it vertically.

Additionally, the first region of the protective layer includes a plurality of first openings and at least one second opening that vertically overlap a plurality of first pads. And, a number of first openings formed in the first region of the protective layer is greater than a number of second openings formed in the first region of the protective layer. That is, the embodiment allows a total number of first openings in the first region to be greater than the total number of second openings in the first region based on a direction of stress applied to the first region, a degree of warpage of the circuit board, and a design of the first pads that overlap vertically with the first region. Accordingly, the embodiment can improve a bonding force between the first pad and the insulating layer while maintaining a bonding force between the first pad and the solder ball. Accordingly, the embodiment can improve the physical reliability of the circuit board. In addition, the embodiment allows the first opening to be formed in more than the second opening in the first region, so that the traces concentrated in the first region can be stably protected, and accordingly, damage to the trace from various factors can be prevented. Additionally, when an external board is bonded to a connection part, the embodiment can improve bonding between the circuit board and the external board. Additionally, when a chip is mounted on the connection part, the embodiment can improve the mount-ability of the chip and thus improve the product reliability of the circuit board.

Additionally, the second region of the protective layer includes at least one first opening and a plurality of second openings that vertically overlap the plurality of second pads. And, the number of second openings formed in the second region of the protective layer is greater than the number of first openings formed in the second region. That is, the embodiment allows the total number of second openings in the second region to be greater than the total number of first openings in the second region based on a direction of stress applied to the second region, a degree of warpage of the circuit board, and a design of the second pads that overlap vertically with the second region. Accordingly, the embodiment can improve the bonding force between the second pad and the insulating layer while maintaining the bonding force between the second pad and the connection part.

Hereinafter, a modified example of the first opening and a structure different from the first opening and the second opening (for example, a combination structure of the first opening and the second opening) will be described.

FIG. 4A is a plan view of a circuit board including a third opening according to a second embodiment, and FIG. 4B is a cross-sectional view of a circuit board of FIG. 4A.

Referring to FIGS. 4A and 4B, the protective layer 160 of the embodiment includes a third opening. The third opening may have a structure that is a combination of the first opening and the second opening described above.

For example, the first-first pad 121-1 of the first embodiment was described as vertically overlapping only with the first-first opening OR1-1, which contains a plurality of unit openings OR1-11 and OR1-12. For example, the first-first pad 121-1 of the first embodiment vertically overlapped only with the plurality of first openings OR1.

Unlike this, the protective layer 160 according to the second embodiment may further include a third opening. The third opening may be spaced apart from the first opening OR1 in the longitudinal or width direction, and may partially overlap vertically with the first-first pad 121-1. Here, the partially overlapping may mean that it includes an overlapping region that vertically overlaps the first-first pad 121-1 and a non-overlapping region that does not vertically overlap the first-first pad 121-1.

At this time, a difference between the first opening OR1, the second opening OR2, and the third opening is briefly explained as follows.

The first opening OR1 has an opening width smaller than the width of the pad. And, an entire region of the first opening OR1 may vertically overlap the pad.

An entire region of the second opening OR2 overlaps vertically with the pad, and the second opening OR2 may have an opening width greater than the width of the pad.

The third opening has an opening width smaller than the width of the pad, and has a structure in which one region overlaps vertically with the pad, and the other region has a structure that does not overlap vertically with the pad. In addition, the third opening may include a third-first opening OR3-1 and a third-second opening OR3-2 described below depending on whether there is a supporting portion of the protective layer in contact with the side surface of the pad in a portion that does not overlap vertically with the pad.

For example, the first-first pad 121-1 vertically overlaps at least one first opening OR1 and at least one third opening. At this time, the third opening may include third-first opening OR3-1 and third-second opening OR3-2 depending on a height of a bottom surface. A bottom surface of the third-first opening OR3-1 may be located at a height corresponding to a lower surface of the first-first pad 121-1, and a bottom surface of the third-second opening OR3-2 may be located higher than a lower surface of the first-first pad 121-1.

Specifically, the first-first pad 121-1 may include a first portion 121-11 that vertically overlaps the first opening OR1. In addition, a portion of the upper surface and the entire side surface of the first-first pad 121-1 adjacent to the first portion 121-11 of the first-first pad 121-1 may be covered with the first region R1 of the protective layer 160 as explained in the first embodiment.

Additionally, the first-first pad 121-1 may include a second portion 121-12 that vertically overlaps the third-first opening OR3-1.

Also, an upper surface 121-12T of the second portion 121-12 of the first-first pad 121-1 may vertically overlap the third-first opening OR3-1. And, the side surface adjacent to the upper surface 121-12T of the second portion 121-12 of the first-first pad 121-1 will partially overlap horizontally with the third-first opening OR3-1.

Specifically, the second portion 121-12 of the first-first pad 121-1 may include a first side surface and a second side surface 121-12S adjacent to the third-first opening OR3-1 and separated in the longitudinal or width direction. An entire first side surface of the second portion 121-12 of the first-first pad 121-1 may be covered with the first region R1 of the protective layer 160.

In addition, an entire second side surface 121-12S of the second portion 121-12 of the first-first pad 121-1 may be spaced apart from the first region R1 of the protective layer 160. For example, the insulating layer 111 may include a non-overlapping region 111S adjacent to the second side surface 121-12S of the second portion 121-12 of the first-first pad 121-1 and does not vertically overlapping the first-first pad 121-1 and the protective layer 160.

Additionally, the first-first pad 121-1 may include a third portion 121-13 that vertically overlaps the third-second opening OR3-2.

Additionally, an upper surface 121-13T of the third portion 121-13 of the first-first pad 121-1 may vertically overlap the third-second opening OR3-2. In addition, a side surface connected to the upper surface 121-13T of the third portion 121-13 of the first-first pad 121-1 may partially overlap horizontally with the third-second opening OR3-2.

For example, the third portion 121-13 of the first-first pad 121-1 may include a first side surface and a second side surface 121-13S adjacent to the third-second opening OR3-2 and separated in the longitudinal or width direction. Also, a first side surface of the third portion 121-13 may be entirely covered with the first region R1 of the protective layer 160. In addition, the second side surface 121-13S of the third portion 121-13 may be partially covered with the first region R1 of the protective layer 160, unlike the second side surface 121-12S of the second portion 121-12. For example, a portion of the second side surface 121-13S of the third portion 121-13 is covered by the support portion 160S of the protective layer 160, and a remaining portion may not be in contact with the protective layer 160.

In the embodiment, a third opening of either the third-first opening OR3-1 or the third-second opening OR3-2 is formed on the first-first pad 121-1.

That is, the first opening OR1 has a structure that entirely covers the side surface of the first-first pad 121-1. Unlike this, the third opening has a structure that completely covers the first side surface of the first-first pad 121-1 and partially covers the second side surface adjacent thereto. Accordingly, the embodiment may further increase the opening width of the first opening OR1 formed on the first-first pad 121-1. For example, the entire region of the first opening OR1 vertically overlaps the first-first pad 121-1. Additionally, only a portion of the third opening vertically overlaps the first-first pad 121-1. The embodiment may be formed by combining the first opening OR1 and the third opening on the first-first pad 121-1. Accordingly, the embodiment can further increase the width of the first opening OR1 compared to the first embodiment, thereby further improving the adhesion between the first-first pad 121-1 and the connection part.

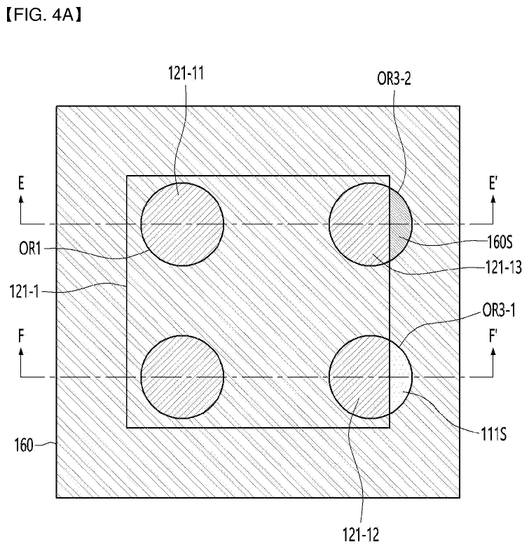

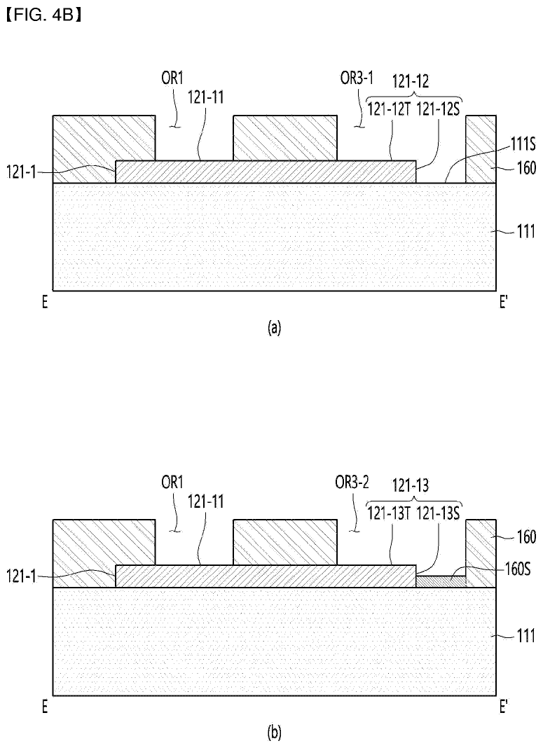

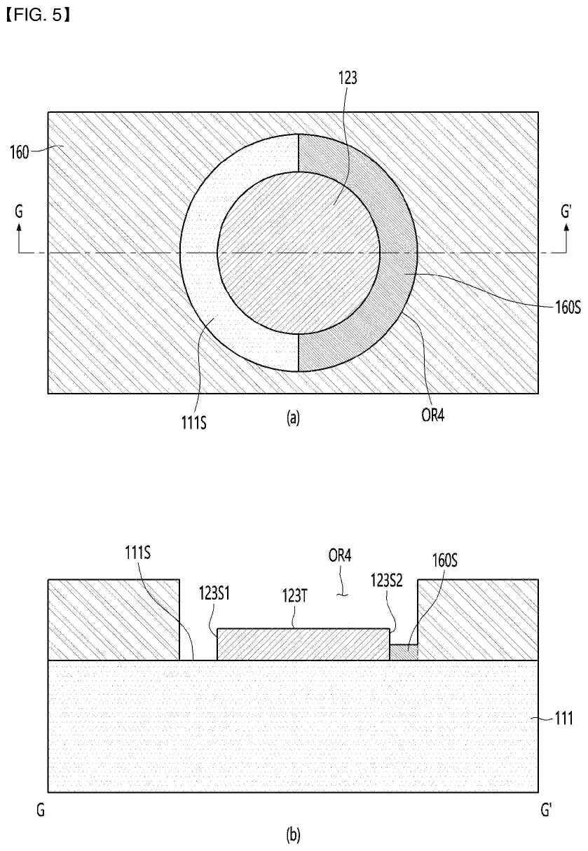

FIG. 5 is a diagram for explaining a fourth opening according to a third embodiment.

FIG. 5 (a) is a plan view of a circuit board including a fourth opening OR4 of a protective layer 160 that vertically overlaps a third pad 123, and FIG. 5 (b) is a cross-sectional view taken along a G-G′ direction of FIG. 5 (a).

Referring to (a) and (b) of FIG. 5, the third pad 123 may vertically overlap the fourth opening OR4 of the protective layer 160. The fourth opening OR4 may be formed in the first region R1 of the protective layer 160, or alternatively, may be formed in the second region R2.

The fourth opening OR4 may have a combination structure of the second-first opening OR2-1 and the second-second opening OR2-2.

For example, the fourth opening OR4 may have a width greater than the width of the third pad 123.

Accordingly, an entire region of an upper surface 123T of the third pad 123 may vertically overlap the fourth opening OR4.

In addition, the side surface of the third pad 123 partially overlaps the fourth opening OR4 horizontally. Accordingly, the side surface of the third pad 123 may be partially covered with the protective layer 160 or may be spaced apart from the protective layer 160.

For example, the third pad 123 may include a first side surface 123S1 and a second side surface 123S2 opposite to the first side surface 123S1.

And, an entire region of the first side surface 123S1 of the third pad 123 may horizontally overlap the fourth opening OR4. Through this, the entire region of the first side surface 123S1 of the third pad 123 may not be in contact with the protective layer 160. For example, the entire region of the first side surface 123S1 of the third pad 123 may be spaced apart from the protective layer 160.

Accordingly, the insulating layer 111 may include a non-overlapping region 111S which is adjacent to the first side surface 123S1 of the third pad 123 and vertically overlaps the fourth opening OR4 without vertically overlapping the third pad 123 and the protective layer 160.

Additionally, the second side surface 123S2 of the third pad 123 may partially overlap the fourth opening OR4 horizontally. For example, a portion of the second side surface 123S2 of the third pad 123 may be covered with the supporting portion 160S of the protective layer 160, and a remaining portion may not be covered by the protective layer 160 and may be spaced apart from the protective layer 160.

In the embodiment, the protective layer includes the fourth opening OR4, thereby further improving the adhesion between the insulating layer 111, the third pad 123, and the connection part.

For example, the second-first opening OR2-1 of the embodiment does not contact the side surface of the pad, and accordingly, the bonding force between the pad and the insulating layer may be reduced. Additionally, since at least a portion of the side surface of the pad is covered with an insulating layer in the second-second opening OR2-2, the bonding area between the pad and the connection part may be reduced by the region covered by the insulating layer. Accordingly, the embodiment allows to have a second-first opening structure on the first side surface of the pad and to provide a fourth opening with a second-second opening structure on the second side surface opposite to the first side surface of the pad. Accordingly, the embodiment can improve the bonding force between the pad and the connection part while improving the bonding force between the insulating layer and the pad.

Hereinafter, the fifth opening according to the embodiment will be described.

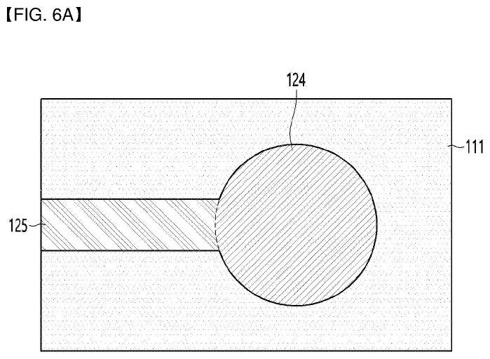

FIG. 6A is a plan view of a circuit pattern layer to which a fifth opening will be applied according to an embodiment, FIG. 6B is a diagram showing a fifth opening according to a first embodiment, and FIG. 6C is a diagram showing a fifth opening according to a second embodiment.

Hereinafter, the fifth opening of the embodiment will be described in detail with reference to FIGS. 6A to 6C.

Referring to FIGS. 6A and 6C, the circuit pattern layer 120 disposed on the insulating layer 111 of the embodiment includes a fourth pad 124 and a first trace 125 disposed on a first side of the fourth pad 124.

At this time, when the structure of the first opening OR1 is applied in the structure including the fourth pad 124 and the first trace 125 as described above, the bonding strength between the fourth pad 124 and the connection part may decrease. And, when the structure of the second opening OR2 is applied in the structure including the fourth pad 124 and the first trace 125, at least a portion of the first trace 125 also vertically overlaps the second opening OR2, and accordingly, the first trace 125 may be damaged from various factors.

Accordingly, the protective layer 160 of the embodiment may include a fifth opening OR5. The fifth opening OR5 may be formed in the first region R1 of the protective layer 160, or alternatively, may be formed in the second region R2 of the protective layer 160.

The fifth opening OR5 includes a region vertically overlapping with the fourth pad 124, and a region that vertically overlaps the insulating layer 111 without vertically overlapping the fourth pad 124.

In addition, the fourth pad 124 includes a region vertically overlapping with the fifth opening OR5 and a region that vertically overlaps the protective layer 160 without vertically overlapping the fifth opening OR5. At this time, a region of the fourth pad 124 that vertically overlaps the protective layer 160 may be a region adjacent to the first trace 125. That is, the embodiment allows the structure of the first opening OR1 to entirely cover the first side surface 124S1 of the fourth pad 124 in one region of the fourth pad 124 adjacent to the first trace 125.

In addition, the embodiment may allow an opening structure on the second side surface of the fourth pad 124, which is opposite to the first side surface 124S1, to have the structure of a second-first opening OR2-1 or the structure of second-second opening OR2-2.

That is, as shown in (a) and (b) of FIG. 6B, the fifth opening OR5-1 may include a support portion 160S that partially covers the second side surface 124S2 opposite to the first side surface 124S1 of the fourth pad 124.

Specifically, when including the fifth opening OR5-1 of FIG. 6B, the central region 124T1 of the upper surface of the fourth pad 124 may vertically overlap the fifth opening OR5-1. Additionally, the outer region of the upper surface of the fourth pad 124 may partially vertically overlap the fifth opening OR5-1.

For example, the first outer region 124T2 adjacent to the first trace 125 in the outer region of the upper surface of the fourth pad 124 may not overlap vertically with the fifth opening OR5-1. For example, the first outer region 124T2 may vertically overlap the protective layer 160 and thus be covered with the protective layer 160.

And, the entire first side surface 124S1 adjacent to the first outer region 124T2 on the side surface of the fourth pad 124 may be covered with the protective layer 160 along with the first outer region 124T2. Accordingly, the first trace 125 disposed adjacent to the first side surface 124S1 can be covered with the protective layer 160, and thus can be stably protected from various factors.

Meanwhile, the second outer region 124T3 excluding the first outer region 124T2 in the outer region of the upper surface of the fourth pad 124 may overlap vertically with the fifth opening OR5-1. And, the second side surface 124S2 of the side surface of the fourth pad 124 adjacent to the second outer region 124T3 may be partially covered by the protective layer 160. For example, at least a portion of the second side surface 124S2 may be spaced apart from the protective layer 160, and the remaining portion may be covered with the support portion 160S of the protective layer 160.

In addition, as shown in (a) and (b) of FIG. 6C, an entire third side surface 124S3 opposite to the first side surface 124S1 of the fourth pad 124 may not be in contact with the protective layer 160 in the fifth opening OR5-2. Through this, the insulating layer 111 adjacent to the third side surface 124S3 may include a non-overlapping region 111S.

Specifically, when including the fifth opening OR5-2 of FIG. 6C, the central region 124T1 of the upper surface of the fourth pad 124 may vertically overlap the fifth opening OR5-2. Additionally, the outer region of the upper surface of the fourth pad 124 may partially vertically overlap the fifth opening OR5-2.

For example, the first outer region 124T2 adjacent to the first trace 125 in the outer region of the upper surface of the fourth pad 124 may not overlap vertically with the fifth opening OR5-2. For example, the first outer region 124T2 may vertically overlap the protective layer 160 and thus be covered with the protective layer 160.

In addition, an entire first side surface 124S1 adjacent to the first outer region 124T2 on the side surface of the fourth pad 124 may be covered with the protective layer 160 along with the first outer region 124T2. Accordingly, the first trace 125 disposed adjacent to the first side surface 124S1 can be covered with the protective layer 160, and thus can be stably protected from various factors.

Meanwhile, the second outer region 124T3 of the outer region of the upper surface of the fourth pad 124 excluding the first outer region 124T2 may overlap vertically with the fifth opening OR5-2. In addition, an entire third side surface 124S3 adjacent to the second outer region 124T3 on the side surface of the fourth pad 124 may be separated from the protective layer 160.

Hereinafter, a sixth opening according to the embodiment will be described.

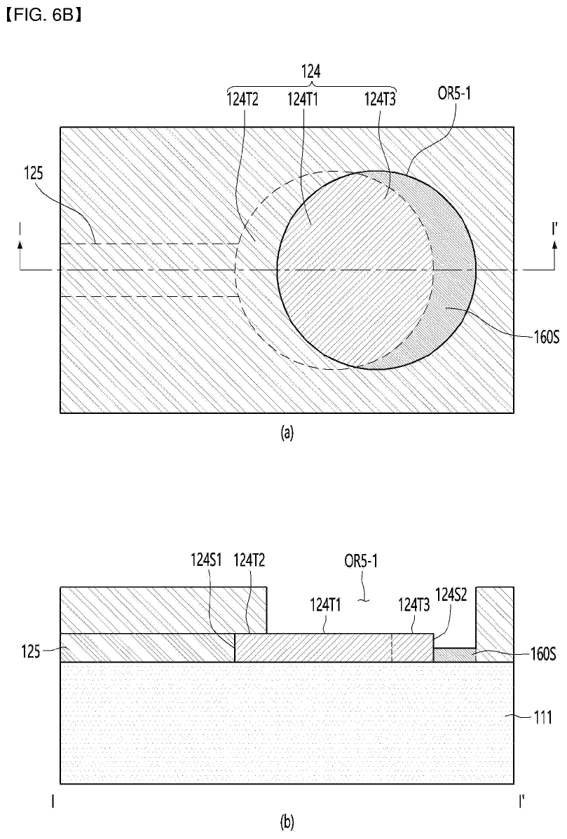

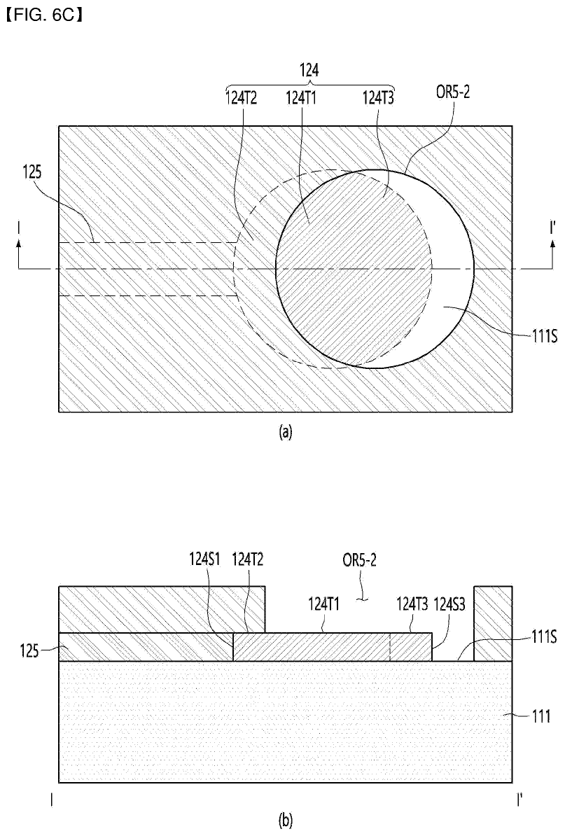

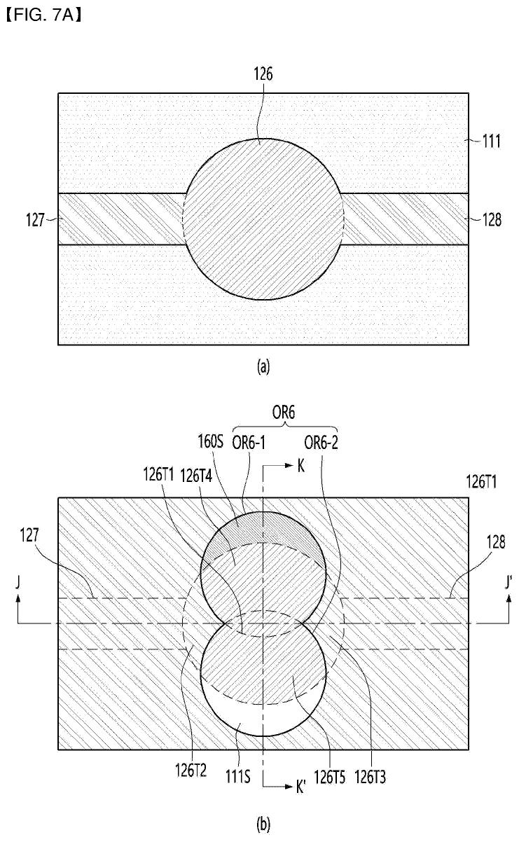

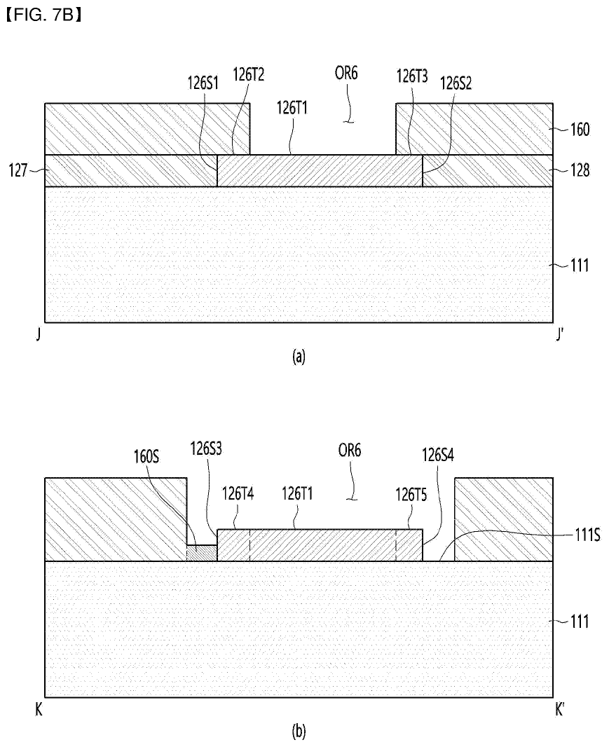

FIG. 7A is a top view of a circuit pattern layer and a protective layer according to an embodiment, and FIG. 7B is a cross-sectional view of FIG. 7A.

Hereinafter, the sixth opening of the embodiment will be described in detail with reference to FIGS. 7A and 7B.

Referring to (a) of FIG. 7A, the circuit pattern layer 120 disposed on the insulating layer 111 of the embodiment includes a fifth pad 126, a second trace 127 disposed at a first side of the fifth pad 126, and a third trace 128 disposed at a second side spaced apart from the first side.

And, when forming an opening on the fifth pad 126 having a structure connected to the second trace 127 and the third trace 128 as described above, the embodiment has the structure of the sixth opening OR6 as shown below.

The sixth opening OR6 may be formed in the first region R1 of the protective layer 160, or alternatively, may be formed in the second region R2 of the protective layer 160.

The sixth opening OR5 includes a region that vertically overlaps the fifth pad 126 and a region that does not vertically overlap the fifth pad 126 but vertically overlaps the insulating layer 111.

In addition, the fifth pad 126 includes a region vertically overlapping with the sixth opening OR6 and a region that does not vertically overlap the sixth opening OR6 but vertically overlaps the protective layer 160. At this time, a region of the fifth pad 126 that vertically overlaps the protective layer 160 may be a region adjacent to the second trace 127 and the third trace 128. That is, in a region of the fifth pad 126 adjacent to the second trace 127 and the third trace 128, the sixth opening OR6 of the embodiment may have a structure of the first opening OR1 that entirely covers the first side surface 126S1 and the second side surface 126S2 of the fifth pad 126. Additionally, the sixth opening OR6 may have the structure of a second-second opening OR2-2 in which the protective layer 160 and the third side surface 126S3 partially contact, in the third side surface 126S3 between the first side surface 126S1 and the second side surface 126S2. Additionally, the sixth opening OR6 may have the structure of a second-first opening OR2-1 in which the entire fourth side surface 126S4 is spaced apart from the protective layer 160, in the fourth side surface 126S4 between the first side surface 126S1 and the second side surface 126S2.

At this time, the sixth opening OR6 may be divided into a plurality of parts. For example, the sixth opening OR6 may be formed of two. That is, the sixth opening OR6 may include a sixth-first opening OR6-1 and a sixth-second opening OR6-2.

That is, the upper surface of the fifth pad 126 may include a central region 126T1 and an outer region. Also, an entire central region 126T1 of the upper surface of the fifth pad 126 may vertically overlap the sixth opening OR6. Additionally, the outer region of the fifth pad 126 may partially overlap the sixth opening OR6.

For example, the outer region of the upper surface of the fifth pad 126 may include a first outer region 126T2 adjacent to the second trace 127. Additionally, the first outer region 126T2 may vertically overlap the protective layer 160 without vertically overlapping the sixth opening OR6. Additionally, the outer region of the upper surface of the fifth pad 126 may include a second outer region 126T3 spaced apart from the first outer region 126T2. Additionally, the second outer region 126T3 may vertically overlap the protective layer 160 without vertically overlapping the sixth opening OR6.

Additionally, the outer region of the upper surface of the fifth pad 126 may include a third outer region 126T4 between one end of the first outer region 126T2 and one end of the second outer region 126T3. And, the third outer region 126T4 may vertically overlap the sixth opening OR6 (specifically, vertically overlap the sixth-first opening). Additionally, the outer region of the upper surface of the fifth pad 126 may include a fourth outer region 126T5 between the other end of the first outer region 126T2 and the other end of the second outer region 126T3. Additionally, the fourth outer region 126T5 may vertically overlap the sixth opening OR6 (specifically, vertically overlap the sixth-second opening).

Accordingly, the first side surface 126S1 of the side surface of the fifth pad 126 is adjacent to the first outer region 126T2 and adjacent to the second trace 127. In addition, the first side surface 126S1 may be entirely covered by the protective layer 160.

In addition, the second side surface 126S2 of the side surface of the fifth pad 126 is adjacent to the second outer region 126T3 and adjacent to the third trace 128. In addition, the second side surface 126S2 may be entirely covered by the protective layer 160.

In addition, a third side surface 126S3 of the side surface of the fifth pad 126 is adjacent to the third outer region 126T4 and is located between one end of the first side surface 126S1 and one end of the second side surface 126S2. In addition, third side surface 126S3 may be partially covered by the protective layer 160. For example, at least a portion of the third side surface 126S3 may be covered by the support portion 160S of the protective layer 160, and the remaining portion may be spaced apart from the protective layer 160.

In addition, the fourth side surface 126S4 of the side surface of the fifth pad 126 is adjacent to the fourth outer region 126T5 and located between the other end of the first side surface 126S1 and the other end of the second side surface 126S2. In addition, the fourth side surface 126S4 may be entirely spaced apart from the protective layer 160. Accordingly, a non-overlapping region 111S of the insulating layer 111 may be included adjacent to the fourth side surface 126S4 of the fifth pad 126.

The embodiment may provide third to sixth openings having various combinations of the first opening OR1 and the second opening OR2, depending on the design of the circuit pattern layer as described above. Through this, the embodiment can stably protect the trace, increase the bonding area between the pad and the connection part, and improve bonding strength between the pad and the insulating layer, depending on the design of the circuit pattern layer.

FIG. 8 is a diagram showing a first package substrate according to an embodiment, and FIG. 9 is a diagram showing a second package substrate according to an embodiment.

A package substrate may have a structure in which a semiconductor device is disposed on the first or second substrate shown in any one of FIGS. 2A to 2G.

For example, referring to FIG. 8, a first package substrate according to an embodiment may have a structure in which the circuit board of FIG. 3A and a chip are mounted on the circuit board.

For example, the package substrate may include a first connection part 210 disposed on the first pad 121 and the second pad 122 of the first circuit pattern layer 120 disposed on the first outermost layer of the circuit board.

The first connection part 210 may have a spherical shape. For example, a cross-section of the first connection part 210 may include a circular shape or a semicircular shape. For example, a cross section of the first connection part 210 may include a partially or entirely rounded shape. For example, a cross-sectional shape of the first connection part 210 may be flat on one side surface and curved on the other side surface. The first connection part 210 may be a solder ball, but is not limited thereto.

The package substrate of the embodiment may include a chip 220 disposed on the first connection part 210. The chip 220 may be a processor chip. For example, the chip 220 may be an application processor (AP) chip of any one of a central processor (e.g., CPU), a graphics processor (e.g., GPU), a digital signal processor, a cryptographic processor, a microprocessor, and a microcontroller.

At this time, a terminal 225 may be included on the lower surface of the chip 220, and the terminal 225 may be electrically connected to the pads 121 and 122 of the first circuit pattern layer 120 of the circuit board through the first connection part 210.

Meanwhile, the package substrate of the embodiment may allow a plurality of chips to be arranged at a certain distance from each other on one circuit board. For example, the chip 220 may include a first chip and a second chip that are spaced apart from each other.

Also, the first chip and the second chip may be different types of application processor (AP) chips.

Meanwhile, the first chip and the second chip may be spaced apart from each other at a certain distance on the circuit board. For example, the distance between the first chip and the second chip may be 150 μm or less. For example, the distance between the first chip and the second chip may be 120 μm or less. For example, the distance between the first chip and the second chip may be 100 μm or less.

Preferably, for example, the distance between the first chip and the second chip may range from 60 um to 150 um. For example, the distance between the first chip and the second chip may range from 70 μm to 120 μm. For example, the distance between the first chip and the second chip may range from 80 um to 110 um. For example, if the distance between the first chip and the second chip is less than 60 um, interference between the first chip and the second chip may cause problems with the operational reliability of the first chip or the second chip. For example, if the distance between the first chip and the second chip is greater than 150 um, signal transmission loss may increase as the distance between the first chip and the second chip increases.

The package substrate may include a molding layer 230. The molding layer 230 may be disposed to cover the chip 220. For example, the molding layer 230 may be EMC (Epoxy Mold Compound) formed to protect the mounted chip 220, but is not limited thereto.

At this time, the molding layer 230 may have a low dielectric constant to increase heat dissipation characteristics. For example, the dielectric constant (Dk) of the molding layer 230 may be 0.2 to 10. For example, the dielectric constant (Dk) of the molding layer 230 may be 0.5 to 8. For example, the dielectric constant (Dk) of the molding layer 230 may be 0.8 to 5. Accordingly, the embodiment allows the molding layer 230 to have a low dielectric constant, thereby improving heat dissipation characteristics for heat generated from the chip 220.

In addition, the first package substrate may include a second connection part 240 disposed on a lowermost side of the circuit board. The second connection part 240 may be for bonding between the package substrate and an external substrate (e.g., a main board of an external device).

Meanwhile, referring to FIG. 9, a second package substrate according to the embodiment includes a substrate additionally coupled to the first package substrate of FIG. 8.

For example, the second package substrate includes a third connection part 310 disposed on the second pad 122 of the first circuit pattern layer 120 in the package substrate of FIG. 8. The third connection part 310 may be formed to have a certain height. For example, the third connection part 310 may have a height higher than the chip 220. Meanwhile, the third connection part 310 may be formed of a solder ball. Alternatively, the third connection part 310 may further include a post bump (not shown) disposed between the solder ball and the second pad.

An upper substrate 300 may be coupled to the third connection part 310. As an example, the upper substrate 300 may be an interposer substrate. For example, the upper substrate 300 may be a connection substrate that connects a memory substrate and the circuit board. As another example, the upper substrate 300 may be a memory substrate.

Meanwhile, the second package substrate includes a lower substrate 400 coupled to the second connection part 240. The lower substrate 400 may correspond to a motherboard of an external device, but is not limited thereto.

Hereinafter, a method of manufacturing a circuit board according to an embodiment will be described.

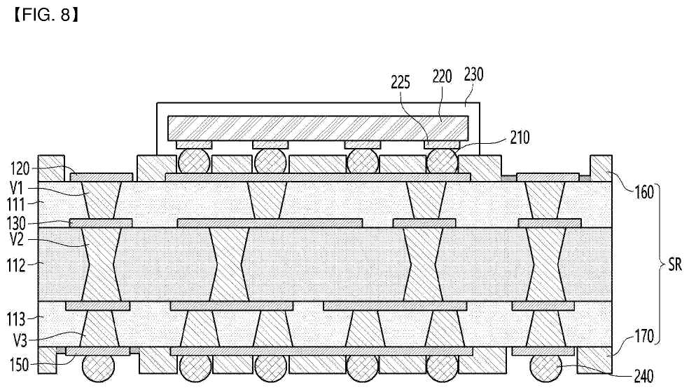

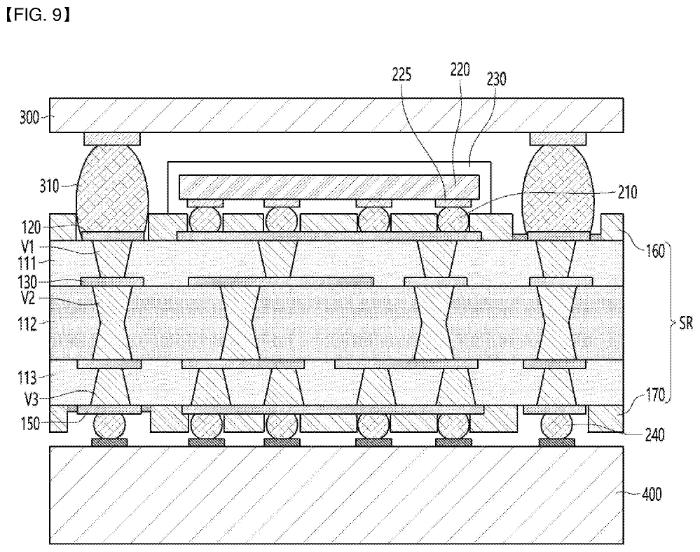

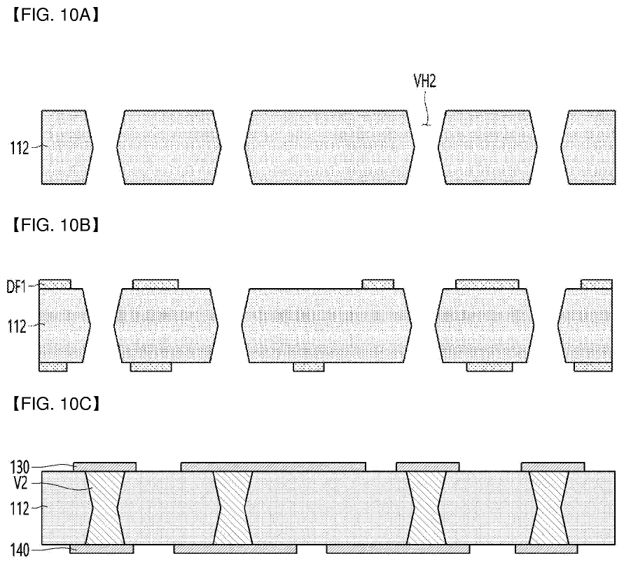

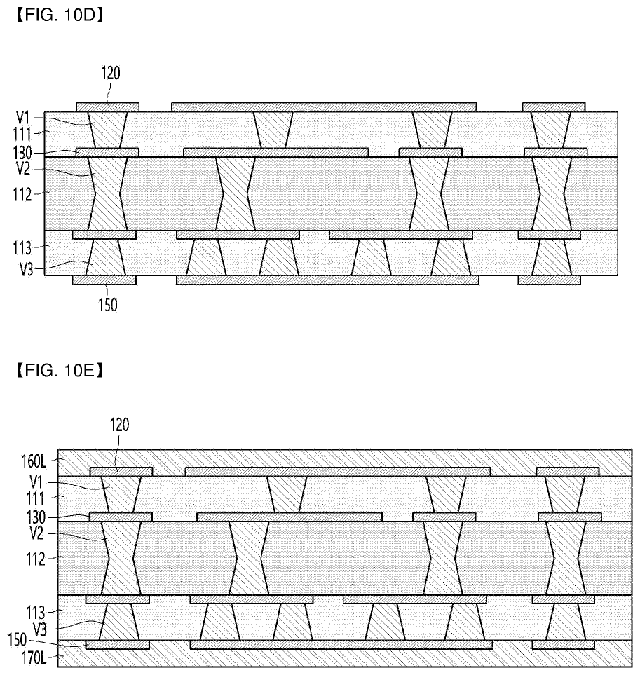

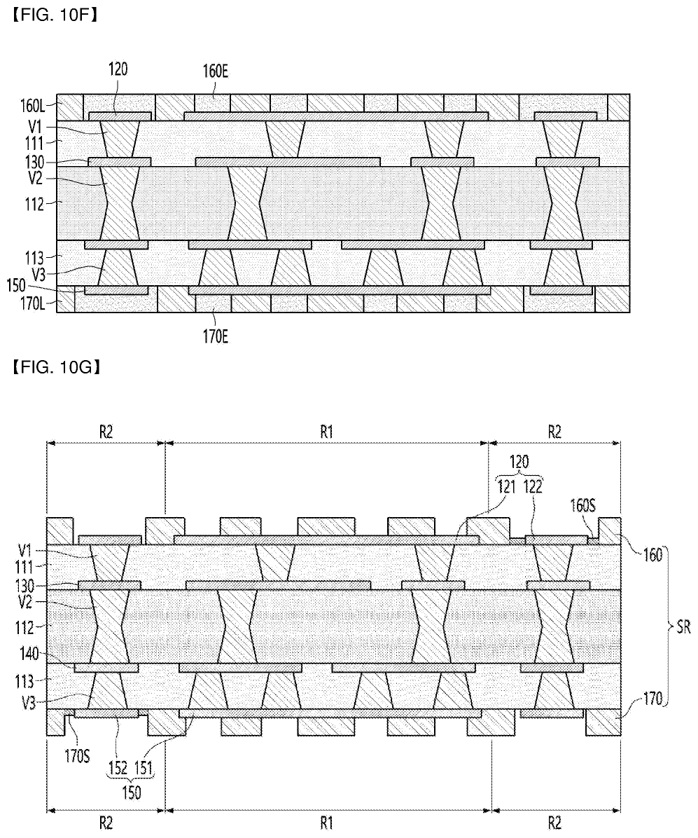

FIGS. 10A to 10G are diagrams showing the method of manufacturing the circuit board according to the first embodiment in order of processes.

Referring to FIG. 10A, in the embodiment, the second insulating layer 112 is prepared. The second insulating layer 112 may be a core layer. And, when the second insulating layer 112 is a core layer, the second insulating layer 112 may be CCL (Copper Clad Laminate). In addition, the embodiment may proceed with a process of forming a second through hole VH2 passing through the second insulating layer 112. At this time, the second insulating layer 112 is a core layer having a certain thickness or more, and accordingly, the process of forming the second through hole VH2 may include a first process of forming a first part of the second through hole VH2 on an upper side of the second insulating layer 112, and a second process of forming a second part connected to the first part of the second through hole VH2 on a lower side of the second insulating layer 112. Accordingly, the second through hole VH2 may have an hourglass shape according to the combination of the first part and the second part. Meanwhile, although not shown in FIG. 8A, copper foil layers (not shown) may be laminated on the upper and lower surfaces of the second insulating layer 112, respectively.

Next, the embodiment may proceed with a process of forming a second through electrode 170 filling the second through hole VH2 of the second insulating layer 112 and a process of forming the second circuit pattern layer 130 disposed on the upper surface of the second insulating layer 112 and the third circuit pattern layer 140 disposed on the lower surface of the second insulating layer 112.

To this end, as shown in FIG. 10B, the embodiment may proceed with a process of forming a dry film DF1 having an opening exposing a region where the second circuit pattern layer 130 and the third circuit pattern layer 140 will be formed on the upper and lower surfaces of the second insulating layer 112.

And, as shown in FIG. 10C, the embodiment may proceed with a process of forming the second through electrode V2, the second circuit pattern layer 130, and the third circuit pattern layer 140 by performing plating to fill the second through holH2 and the opening of the dry film DF1. At this time, the embodiment allows electroless plating to be performed on the second insulating layer 112 or the copper foil layer (not shown) to form a chemical copper plating layer (not shown), and accordingly, the plating may be performed using the chemical copper plating layer as a seed layer.

Next, as shown in FIG. 10D, the embodiment may proceed with a process of laminating the first insulating layer 111 on the first or upper surface of the second insulating layer 112 and a process of laminating the third insulating layer 113 on the second or lower surface of the second insulating layer 112 may be performed.

At this time, the first insulating layer 111 and the third insulating layer 113 may be prepreg or, alternatively, may be RCC.

In addition, although not shown in the drawing, a copper foil layer (not shown) may be formed on the first surface of the first insulating layer 111 and the second surface of the third insulating layer 113, respectively.

Next, the embodiment may proceed with a process of forming a first through electrode V1 and a third through electrode V3 to fill the through hole VH1 and VH3, and a process of forming a first circuit pattern layer 120 on the upper surface of the first insulating layer 111 and a fourth circuit pattern layer 150 on the lower surface of the third insulating layer 113, by plating.

Next, as shown in FIG. 10E, the embodiment is a process of forming a first solder resist layer 160L on the upper surface of the first insulating layer 111 and a process of forming a second solder resist layer 170L on the lower surface of the third insulating layer 113. At this time, the first solder resist layer 160L and the second solder resist layer 170L may be formed entirely on the upper part of the first insulating layer 111 and the lower part of the third insulating layer 113.

Next, as shown in FIG. 10F, the embodiment may proceed with a process of exposing the first solder resist layer 160L and the second solder resist layer 170L, respectively.

For example, the embodiment may proceed with a process of exposing the remaining regions of the first solder resist layer 160L except a development region 160E1 where the first opening OR1 and the second opening OR2 will be formed.

Correspondingly, the embodiment may proceed with a process of exposing the remaining regions of the second solder resist layer 170L except a development region 170E where the first opening OR1 and the second opening OR2 will be formed.

Thereafter, the embodiment may proceed with a process of curing the exposed region according to the exposure process. However, the curing process may not be carried out separately but may be carried out together with the exposure process.

Next, as shown in FIG. 10G, the embodiment may proceed with a process of forming an opening by developing the development regions (160E1, 160E2, 170E) excluding the cured region.

At this time, in order to form the opening, the embodiment may proceed with a process of thinning the uncured regions 160E and 170E to reduce the thickness of the solder resist layer in the corresponding region. At this time, the thinning can be performed on the unexposed region using an organic alkaline compound containing tetramethylammonium hydroxide (TMAH) or trimethyl-2-hydroxyethylammonium hydroxide (choline).

Accordingly, the embodiment can adjust thinning conditions to correspond to the shape of the opening to be formed in each development region in the first solder resist layer 160L and the second solder resist layer 170. Through this, the embodiment can form a first protective layer 160 and a second protective layer 170 with openings formed.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

1. A circuit board comprising:
an insulating layer;
plurality of pads disposed on the insulating layer and spaced apart from tach other along a horizontal direction; and
a protective layer disposed on the insulating layer and including an opening overlapping the plurality of pads along a vertical direction,
wherein the opening includes a plurality of first openings, and a plurality of second openings including inner walls having a vertical length greater than a vertical length of inner walls of the plurality of first openings,
wherein the plurality of first openings have a first length along the vertical direction, and
wherein the plurality of second openings includes a second-first opening having a second length greater than the first length along the vertical direction and a second-second opening having a third length greater than the first length and less than the second length along the vertical direction,
wherein the second-second opening includes an overlapping region that overlaps the pad along the horizontal direction, and
wherein the overlapping region does not overlap with the first opening along the horizontal direction and overlaps with the second-first opening along the horizontal direction.

2. The circuit board of claim 1, wherein the protective layer includes a first region of a central region and a second region of an outer region excluding the central region,
wherein the plurality of first openings are provided in each of the first and second regions, and
wherein a number of first openings formed in the first region of the protective layer is greater than a number of first openings formed in the second region of the protective layer.

3. The circuit board of claim 2, wherein the plurality of second openings are provided in each of the first and second regions, and
wherein a number of second openings formed in the second region of the protective layer is greater than a number of second openings formed in the first region of the protective layer.

4. The circuit board of claim 3, wherein the number of first openings formed in the first region of the protective layer is greater than the number of second openings formed in the first region of the protective layer, and
wherein the number of second openings formed in the second region of the protective layer is greater than the number of first openings formed in the second region of the protective layer.

5. The circuit board of claim 3, wherein the first region of the protective layer is a central region of a chip mounting region, and
wherein the second region of the protective layer is an outer region of the chip mounting region excluding the central region of the chip mounting region.

6. The circuit board of claim 3, wherein the first region of the protective layer is a central region of an entire upper region or an entire lower region of the insulating layer, and
wherein the second region of the protective layer is an outer region of the entire upper region or the entire lower region excluding the central region of the entire upper region or the entire lower region.

7. The circuit board of claim 3, wherein the plurality of pads include at least one of a first pad and a second pad overlapping the first opening along a vertical direction,
wherein the first pad vertically overlaps a plurality of first openings spaced apart in different horizontal directions, and
wherein the second pad vertically overlaps one first opening.

8. The circuit board of claim 7, wherein the plurality of pads further include a third pad overlapping the second-first opening along the vertical direction,
wherein a width of the second-first opening in the horizontal direction is greater than a width of the third pad in the horizontal direction, and
wherein a side surface of the third pad is in non-contact with an inner wall of the second-first opening.

9. The circuit board of claim 7, wherein the plurality of pads include a fourth pad overlapping the second-second opening along the vertical direction,
wherein a width of the second-second opening in the horizontal direction is greater than a width of the fourth pad in the horizontal direction,
wherein a bottom surface of the second-second opening is located between an upper surface of the fourth pad and a lower surface of the fourth pad, and
wherein a side surface of the fourth pad includes a contact surface in contact with an inner wall of the second-second opening and a non-contact surface spaced horizontally from the inner wall of the second-second opening.

10. The circuit board of claim 7, wherein a plurality of first pads are spaced apart along the horizontal direction,
wherein the protective layer further includes a third opening partially overlapping one of the plurality of first pads along the vertical direction,
wherein the third opening is spaced apart from the first opening along the horizontal direction, and
wherein the third opening has a width smaller than a width of a first pad overlapping the third opening along the vertical direction.

11. The circuit board of claim 10, wherein a central axis in the horizontal direction of the third opening is misaligned with a central axis in the horizontal direction of a first pad overlapping the third opening along the vertical direction.

12. The circuit board of claim 11, wherein a side surface of the first pad overlapping the third opening along the vertical direction includes a contact surface in contact with an inner wall of the third opening; and a non-contact surface connected to the contact surface and spaced apart from the inner wall of the third opening in the horizontal direction.

13. The circuit board of claim 1, wherein the plurality of pads further includes a fifth pad,
wherein the protective layer further includes a fourth opening overlapping the fifth pad along the vertical direction,
wherein a width of the fourth opening in the horizontal direction is greater than a width of the fifth pad in the horizontal direction,

14. The circuit board of claim 13, wherein a side surface of the fifth pad includes:
a first side surface located at one side of the fourth opening and spaced apart from an inner wall of the fourth opening in the horizontal direction; and
a second side surface connected to the first side surface, located at other side of the fourth opening, and partially contacting the inner wall of the fourth opening.

15. The circuit board of claim 14, wherein the second side surface incudes:
a first portion connected to the first side surface, adjacent to a lower surface of the fifth pad, and connected to the inner wall of the fourth opening; and
a second portion located on the first portion, connected to the first side surface, adjacent to a lower surface of the fourth pad, and spaced apart from the inner wall of the fourth opening.

16. The circuit board of claim 14, wherein the plurality of pads further includes a sixth pad,
wherein a trace is connected to a first side surface of the sixth pad,
wherein the protective layer includes a fifth opening partially overlapping the sixth pad along the vertical direction,
wherein an upper surface of the sixth pad includes:
an overlapping region overlapping the fifth opening along the vertical direction,
a non-overlapping region that does not overlap the fifth opening along the vertical direction.

17. The circuit board of claim 16, wherein the non-overlapping region includes a first outer region of an upper surface of the sixth pad adjacent to the first side surface of the sixth pad.

18. The circuit board of claim 17, wherein the overlapping region includes:
a central region of the upper surface of the sixth pad,
a second outer region excluding the first outer region among the outer regions of the upper surface of the sixth pad.

19. The circuit board of claim 17, wherein the first side surface of the sixth pad and the trace are covered with the protective layer.

20. The circuit board of claim 18, wherein the sixth pad includes a second side surface adjacent to the second outer region, and
wherein at least a portion of the second side surface of the sixth pad overlaps the fifth opening in the horizontal direction and does not contact the protective layer.
